(19) United States
(12) Patent Application Publication
(10) Pub. No.: US 2026/0219586 A1
(43) Pub. Date: Jul. 30, 2026

(54) EXPOSURE DEVICE AND SUBSTRATE SUPPORT MEMBER

(71) Applicant: NIKON CORPORATION, Tokyo (JP)

(72) Inventors: Atsushi HARA, Yokohama-shi (JP); Yutaro FUJITA, Shibata-gun (JP)

(73) Assignee: NIKON CORPORATION, Tokyo (JP)

(21) Appl. No.: 19/574,601

(22) Filed: Mar. 23, 2026

Related U.S. Application Data
(63) Continuation of application No. PCT/JP2023/035129, filed on Sep. 27, 2023.

(51) Int. Cl. G03F 7/00; G03F 7/20

(52) U.S. Cl. CPC G03F 7/70716; G03F 7/20

(57) ABSTRACT

An exposure device includes a neutralization portion that eliminates static electricity charged on a substrate support member while the substrate support member supporting a substrate moves, wherein the substrate support member includes a main body portion that is conductive, and a conductive member that faces the substrate supported by the substrate support member and is electrically connected to the main body portion, and the neutralization portion eliminates static electricity charged on the main body portion.

### CROSS-REFERENCE TO RELATED APPLICATION

This application is a continuation application of the prior International Patent Application No. PCT/JP2023/035129, filed on September 27, 2023, the entire contents of which are incorporated herein by reference.

### FIELD

The present disclosure relates to an exposure device and a substrate support member.

### BACKGROUND

In a photolithography process for manufacturing a semiconductor device, a liquid crystal display device, and the like, a step-and-repeat projection exposure device (so-called stepper), a step-and-scan projection exposure device (so-called scanning stepper (also called a scanner)), or the like is mainly used to transfer a pattern formed on a mask or a reticle onto a glass substrate, a wafer, or the like through a projection optical system.

In such exposure devices, various measures against static electricity are taken to remove static electricity charged on the substrate and the mask as disclosed in, for example, Japanese Patent Application Publication No. H08-137112.

### SUMMARY

According to an aspect of the present disclosure, there is provided an exposure device including: a neutralization portion that eliminates static electricity charged on a substrate support member while the substrate support member supporting a substrate moves, wherein the substrate support member includes a main body portion that is conductive, and a conductive member that faces the substrate supported by the substrate support member and is electrically connected to the main body portion, and wherein the neutralization portion eliminates static electricity charged on the main body portion.

According to another aspect of the present disclosure, there is provided a substrate support member that supports a substrate to be moved, including: a main body portion that is conductive; a conductive member that faces the substrate and is electrically connected to the main body portion; and a discharge cable electrically connected to the main body portion.

According to another aspect of the present disclosure, there is provided a substrate support member that supports a substrate to be moved, including: a main body portion that is conductive; at least one of a neutralization brush or a support member having conductivity, the neutralization brush being electrically connected to the main body portion and having a conductive bristle bundle extending toward the substrate, the support member being electrically connected to the main body portion, supporting the substrate by being in contact with the substrate, and having conductivity; and a discharge cable electrically connected to the main body portion.

According to another aspect of the present disclosure, there is provided an exposure device including: a neutralization portion that eliminates static electricity charged on a substrate support member while the substrate support member supporting a substrate moves, wherein the substrate support member includes: a main body portion that is conductive; and at least one of a neutralization brush or a support member having conductivity, the neutralization brush being electrically connected to the main body portion and having a conductive bristle bundle extending toward the substrate, the support member being electrically connected to the main body portion and configured to support the substrate by being in contact with the substrate, and wherein the neutralization portion eliminates static electricity charged on the main body portion.

The configuration of the embodiments described below may be modified appropriately, and at least one or some of the components may be substituted for other components. Further, the constituent elements whose arrangement is not particularly limited are not limited to the arrangement disclosed in the embodiments, and can be arranged at positions where the functions can be achieved.

### BRIEF DESCRIPTION OF DRAWINGS

FIG. 1 is a schematic view illustrating a configuration of an exposure device according to an embodiment;

FIG. 2A is a schematic view of a main body and a substrate transfer device as viewed from above, and FIG. 2B is a schematic view of the main body and the substrate transfer device as viewed from the side;

FIG. 3A is a top view of a substrate tray, and FIG. 3B is a side view of the substrate tray on which a substrate is placed;

FIG. 4 is a view of a transfer mechanism as viewed from an +X side;

FIG. 5A is a diagram for describing a relationship among a substrate holder, the transfer mechanism, and a neutralization brush, and FIG. 5B is a diagram for describing a relationship between the neutralization brush and the substrate tray;

FIG. 6 is a diagram for describing another example of the installation location of the neutralization brush;

FIG. 7A to FIG. 7C are diagrams for describing a robot hand according to a variation of the present embodiment;

FIG. 8 is a view (No. 1) for describing the configuration of a mask loader;

FIG. 9 is a view (No. 2) for describing the configuration of the mask loader;

FIG. 10 is a flowchart illustrating a series of processes until a mask is loaded onto a mask stage;

FIG. 11 is a flowchart illustrating a series of processes after the mask is unloaded from the mask stage;

FIG. 12 is a cross-sectional view for describing the configuration of a mask case;

FIG. 13 is a cross-sectional view illustrating another configuration example of the mask case;

FIG. 14A is a view illustrating an overview of a transport cart, and FIG. 14B is an enlarged view of a mechanical stopper;

FIG. 15A and FIG. 15B are diagrams for describing a structure of a neutralization mechanism included in the transport cart;

FIG. 16A is a schematic view of a shelf portion of a mask buffer as viewed from a +Z direction, and FIG. 16B is a cross-sectional view taken along line A-A in FIG. 16A;

FIG. 17 is a schematic diagram illustrating a configuration of a buffer arm; and

FIG. 18A is a diagram illustrating an appearance of a mask transfer mechanism according to the embodiment, and FIG. 18B is a schematic diagram illustrating a configuration of the mask transfer mechanism.

### DESCRIPTION OF EMBODIMENTS

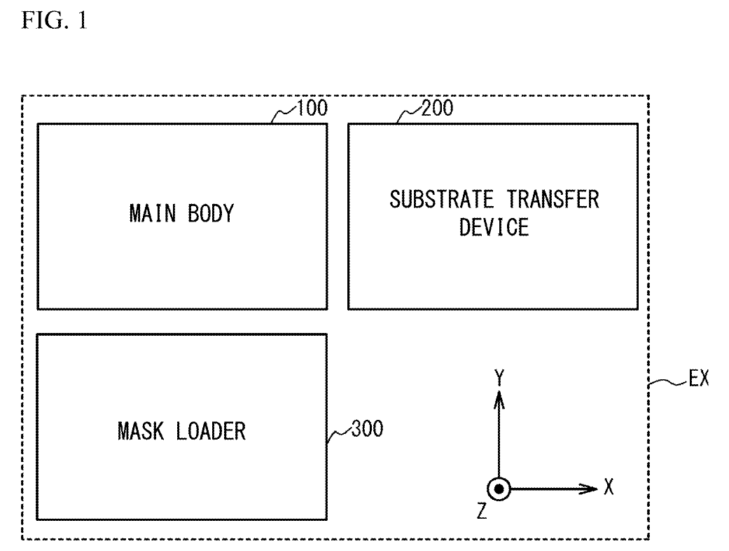

Hereinafter, an exposure device EX according to an embodiment will be described with reference to FIG. 1 to FIG. 18B. FIG. 1 is a schematic view illustrating a configuration of the exposure device EX according to the embodiment.

The exposure device EX is used, for example, when manufacturing an organic EL display, or when forming a touch panel (TP) circuit or a color filter (CF) circuit on the upper surface of a substrate P. The substrate P is, for example, a glass plate on which a thin film transistor (TFT) is formed by vapor deposition or the like, followed by sealing treatment, but is not limited thereto.

As illustrated in FIG. 1, the exposure device EX includes a main body 100, a substrate transfer device 200, and a mask loader 300.

Hereinafter, the direction in which a mask M and a substrate P, which will be described later, are scanned relative to a projection optical system 116 during exposure is referred to as an X-axis direction, the direction orthogonal to the X-axis in the horizontal plane is referred to as a Y-axis direction, the direction orthogonal to the X-axis and the Y-axis is referred to as a Z-axis direction, and the rotation (inclination) directions about the X-axis, the Y-axis, and the Z-axis are referred to as θx, θy, and θz directions, respectively.

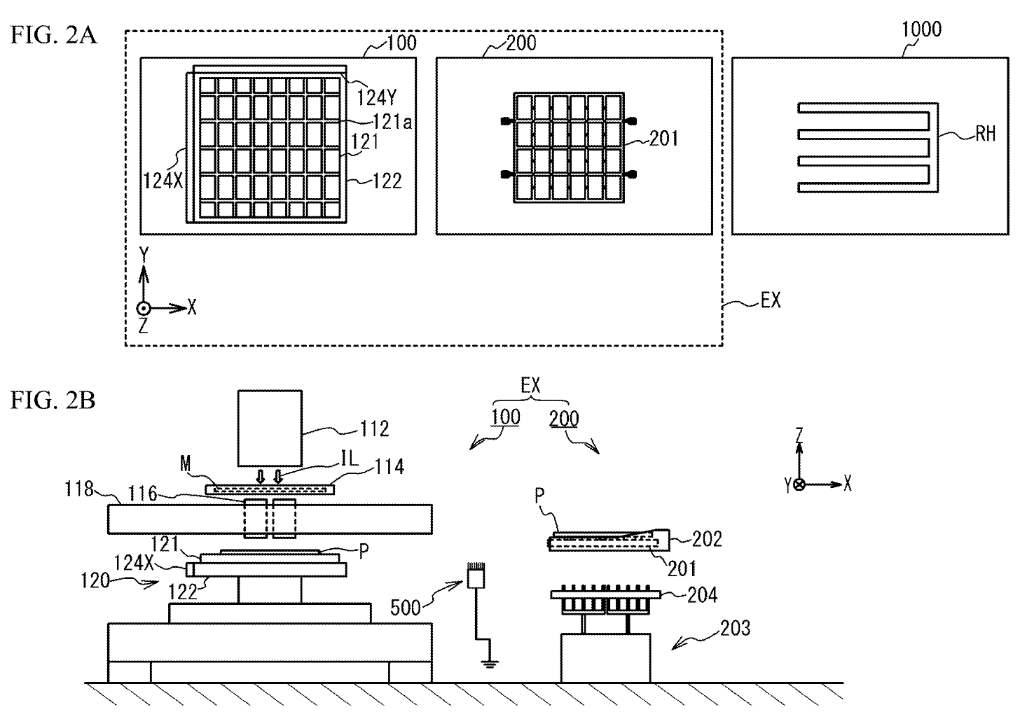

FIG. 2A is a schematic view of the main body 100 and the substrate transfer device 200 as viewed from above, and FIG. 2B is a schematic view of the main body 100 and the substrate transfer device 200 as viewed from the side. As illustrated in FIG. 1, FIG. 2A, and FIG. 2B, the substrate transfer device 200 is disposed at the +X side of the main body 100. The substrate transfer device 200 may be disposed at the -X side of the main body 100.

Substrate transfer device 200

The substrate transfer device 200 delivers the substrate P between an external device 1000 (see FIG. 2A) such as a coater/developer and the main body 100. The external device 1000 has, for example, a fork-shaped robot hand RH, and can carry the substrate P placed on the robot hand RH from the external device 1000 into the substrate transfer device 200.

The substrate transfer device 200 includes a substrate tray (substrate support member) 201, a transfer mechanism 202, an alignment mechanism 203, and a pedestal unit 204.

The substrate tray 201 is placed on the pedestal unit 204. The substrate P placed on the robot hand RH is transported from the external device 1000 into the substrate transfer device 200, and placed on the substrate tray 201 placed on the pedestal unit 204.

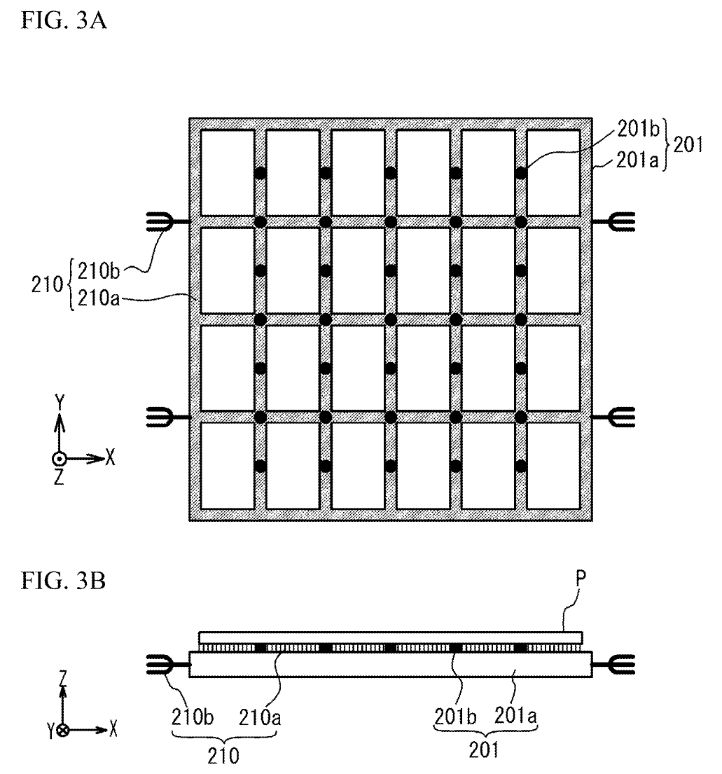

The substrate tray 201 is a carrier used when the substrate P is carried and installed inside the main body 100, and the substrate P is placed on the upper surface of the substrate tray 201. FIG. 3A is a top view of the substrate tray 201, and FIG. 3B is a side view of the substrate tray 201 on which the substrate P is placed.

As illustrated in FIG. 3A, the substrate tray 201 is, for example, a lattice-shaped member. The substrate tray 201 includes a base member 201a and support members 201b that are provided on the base member 201a and support the substrate P. In the present embodiment, the base member 201a and the support members 201b have conductivity, and the base member 201a and the support member 201b are electrically connected to each other. In the present description, “having conductivity” or “conductive” means having either one of electrostatic conductivity and electrostatic diffusivity. The electrostatic conductive material is a material having a surface resistance value of 1 × 10² ≤ Rs < 1 × 10⁴ Ω, and the electrostatic dissipative material is a material having a surface resistance value of 1 × 10⁴ ≤ Rs < 1 × 10¹¹ Ω.

In the present embodiment, the substrate tray 201 includes a neutralization mechanism 210 for removing static electricity charged on the substrate P.

The neutralization mechanism 210 includes a neutralization brush 210a and discharge cables 210b. The neutralization brush 210a has conductive bristle bundles (conductive fibers). The neutralization brush 210a is electrically connected to the base member 201a, and guides the static electricity charged on the substrate P supported by the support members 201b to the base member 201a. In the present embodiment, the support members 201b are also conductive and are electrically connected to the base member 201a. Therefore, the support members 201b also guide the static electricity charged on the substrate P to the base member 201a, but the support members 201b may be electrically non-conductive.

The discharge cable 210b is electrically connected to the base member 201a. The discharge cable 210b is also called a static discharger, and discharges the static electricity guided to the base member 201a into the air. This allows static electricity charged on the substrate P placed on the substrate tray 201 to be removed, thereby inhibiting devices such as TFTs formed on the substrate P from being damaged by a discharge phenomenon of static electricity.

The substrate tray 201 has a size that allows the substrate P, for example, of G6 (1850 × 1500 mm) size, to be placed without the substrate P protruding from the substrate tray 201. That is, the substrate tray 201 has a size that allows two substrates P of G6 half size, which is obtained by splitting the substrate P of a G6 (1850 × 1500 mm) size in half, to be placed thereon. The size of the substrate P placed on the substrate tray 201 is not limited to the G6 size, and may be a size larger than the G6 size or a size smaller than the G6 size. When the size of the substrate P placed on the substrate tray 201 is larger than the G6 size, the size of the substrate tray 201 is designed so that the substrate P can be placed without protruding from the substrate tray 201. Further, the number of the substrates P placed on the substrate tray 201 is not limited to one or two, and may be three or more.

The alignment mechanism 203 positions the substrate P with respect to the substrate tray 201 based on the position of the substrate P detected by a position detection sensor (not illustrated). The substrate P is transported into the inside of the main body 100 while being disposed on the substrate tray 201. As the alignment mechanism 203, for example, a configuration described in International Publication No. WO2023/190110 can be adopted, but other configurations may be adopted.

The transfer mechanism 202 transports the substrate tray 201 holding the positioned substrate P to the main body 100. Further, the transfer mechanism 202 carries out the substrate tray 201 disposed inside the main body 100 from the main body 100.

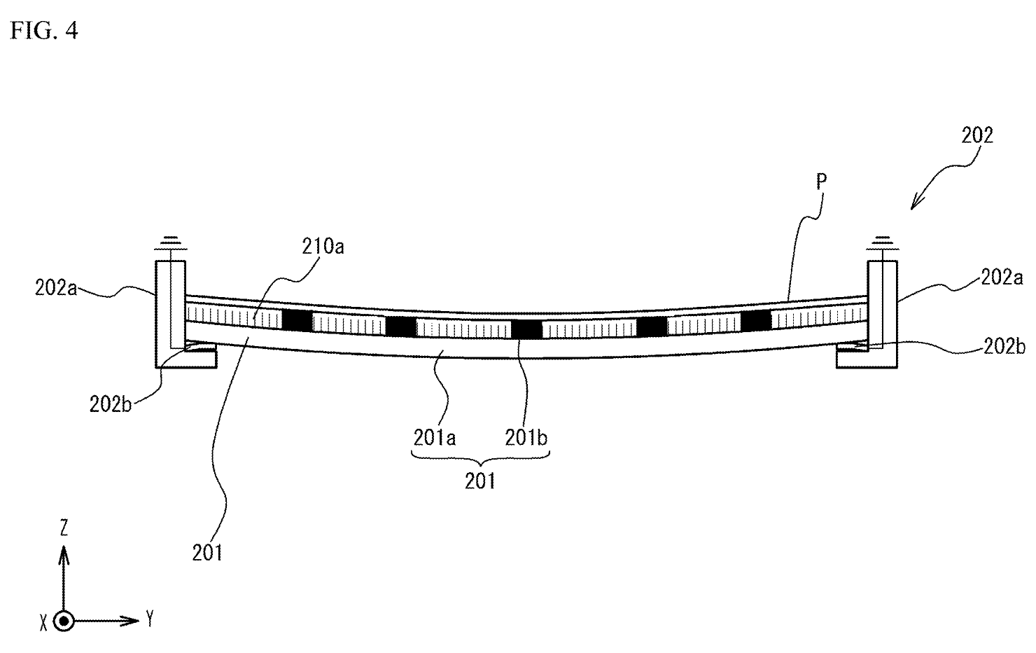

FIG. 4 is a view of the transfer mechanism 202 as viewed from the +X side. The transfer mechanism 202 has transfer arms 202a. The transfer arms 202a grip the substrate tray 201 from both sides in the Y-axis direction, for example. In that state, the transfer mechanism 202 is moved along the X-axis direction by a moving mechanism (not illustrated). Thus, the substrate tray 201 is transferred by the transfer mechanism 202.

A conductive component 202b is attached to the transfer arm 202a, and the conductive component 202b is grounded via a wire. As illustrated in FIG. 4, in a state in which the transfer arms 202a grip the substrate tray 201, the conductive components 202b are in contact with the base member 201a of the substrate tray 201. This electrically connects the conductive components 202b and the substrate tray 201, and thus the static electricity guided to the base member 201a is removed. Therefore, it is possible to inhibit the substrate P from being charged with static electricity while the substrate P is transferred by the transfer mechanism 202, and to inhibit devices such as TFTs formed on the substrate P from being damaged by a discharge phenomenon of the static electricity.

Main body 100

Next, a configuration of the main body 100 will be described. As illustrated in FIG. 2B, the main body 100 includes an illumination system 112, a mask stage 114 that holds a mask M on which a circuit pattern or the like is formed, the projection optical system 116, an optical surface plate 118, and a substrate stage device 120 that holds the substrate P.

The illumination system 112 is configured similarly to the illumination system disclosed in, for example, U.S. Patent No. 5,729,331 and the like. The illumination system 112 irradiates the mask M with light emitted from a light source (e.g., a mercury lamp) (not illustrated) as exposure illumination light (illumination light) IL via a reflecting mirror, a dichroic mirror, a shutter, a wavelength selection filter, various lenses, and the like (not illustrated).

The mask stage 114 holds a light transmissive mask M. The mask stage 114 drives the mask M with a predetermined stroke in the X-axis direction (scanning direction) with respect to the illumination system 112 (illumination light IL) via a drive system (not illustrated) including, for example, a linear motor, and also finely drives the mask M in the Y-axis direction and the θz direction. The position information of the mask M in the horizontal plane is obtained by a mask stage position measurement system (not illustrated) including, for example, a laser interferometer or an encoder.

The projection optical system 116 is disposed below the mask stage 114. The projection optical system 116 is a so-called multi-lens projection optical system having a configuration similar to that of a projection optical system disclosed in, for example, U.S. Patent No. 6,552,775, and includes a plurality of optical systems that form erect images in a both-side telecentric equal-magnification system, for example.

In the main body 100, when the illumination area on the mask M is illuminated by the illumination light IL from the illumination system 112, a projection image (partially erected image) of the circuit pattern of the mask M in the illumination area is formed in an irradiation area (exposure area) of the illumination light conjugate with the illumination area on the substrate P through the projection optical system 116 by the illumination light passing through the mask M. Then, the mask M moves relative to the illumination area (illumination light IL) in the scanning direction, and the substrate P moves relative to the exposure area (illumination light IL) in the scanning direction, whereby scanning exposure of one shot area on the substrate P is performed, and the pattern formed on the mask M is transferred to the shot area.

The optical surface plate 118 supports the mask stage 114 and the projection optical system 116.

The substrate stage device 120 is for positioning the substrate P with high accuracy with respect to the projection optical system 116 (illumination light IL), and includes a substrate holder 121 that holds the substrate P, and a substrate stage 122.

As illustrated in FIG. 2A, the substrate holder 121 includes an accommodating portion 121a. The accommodating portion 121a is a groove formed in the substrate holder 121, and accommodates the substrate tray 201. As a result, the substrate tray 201 holding the substrate P is accommodated in the accommodating portion 121a, and thereby the substrate P is disposed on the upper surface of the substrate holder 121.

The substrate stage 122 is driven by a driving device (not illustrated) with a predetermined stroke along a horizontal plane (X-axis direction and Y-axis direction), and is finely driven in directions of six degrees of freedom. The configuration of the substrate stage device 120 is not particularly limited, but it is preferable to use a stage device of a so-called coarse/fine movement configuration including a gantry type two dimensional coarse movement stage and a fine movement stage finely driven with respect to the two dimensional coarse movement stage, as is disclosed in, for example, Japanese Patent Application Publication No. 2004-14915, U.S. Patent Application Publication No. 2012/0057140, or the like.

As illustrated in FIG. 2A, an X moving mirror (bar mirror) 124X having a reflecting surface perpendicular to the X-axis is fixed to the -X-side side surface of the substrate stage 122, and a Y moving mirror 124Y having a reflecting surface perpendicular to the Y-axis is fixed to the +Y-side side surface.

To the optical surface plate 118, first and second laser interferometers (not illustrated) are attached, which respectively measure the position in the X-axis direction and the position in the Y-axis direction of the substrate holder 121 that holds substrate P.

The first laser interferometer irradiates the X moving mirror 124X and an X fixed mirror (not illustrated) fixed near the projection optical system 116 with a measurement beam. The first laser interferometer measures the position information of the substrate holder 121 in the X-axis direction with reference to the position of the X fixed mirror.

The second laser interferometer irradiates the Y moving mirror 124Y and a Y fixed mirror (not illustrated) fixed near the projection optical system 116 with a measurement beam. The second laser interferometer measures positional information of the substrate holder 121 in the Y-axis direction with reference to the position of the Y fixed mirror.

A control device (not illustrated) drives the substrate stage 122 based on position information (including rotation information (yawing amount (rotation amount θz in the θz direction), pitching amount (rotation amount θy in the θy direction), and rolling amount (rotation amount θx in the θx direction)) of the substrate stage 122 in the XY plane measured by the first laser interferometer and the second laser interferometer.

In the main body 100, alignment measurement (for example, EGA or the like) is performed prior to exposure, and the substrate P is exposed in the following procedure using the results. First, the mask stage 114 and the substrate stage 122 are synchronously driven in the X-axis direction in accordance with an instruction from a control device (not illustrated). Thus, scanning exposure is performed on the first shot area on the substrate P. When the scanning exposure of the first shot area is completed, the control device (not illustrated) moves (steps) the substrate stage 122 to a position corresponding to the second shot area. Then, scanning exposure is performed on the second shot area. Similarly, the control device (not illustrated) repeats stepping between shot areas of the substrate P and scanning exposure on the shot areas, thereby transferring the pattern of the mask M to all the shot areas on the substrate P.

In the exposure device EX according to the present embodiment, an X-ray ionizer is provided in the main body 100 in order to remove static electricity charged on the substrate P placed on the substrate holder 121. In addition, in the substrate transfer device 200, an X-ray ionizer is provided in order to remove static electricity charged on the substrate P placed on the substrate tray 201 held by the pedestal unit 204. The X-ray ionizer may be provided in either the main body 100 or the substrate transfer device 200.

However, if static electricity is charged on the substrate P and the charged static electricity is discharged while the transfer mechanism 202 transfers the substrate P between the pedestal unit 204 and the substrate holder 121, there is a concern that devices such as TFTs formed on the substrate P may be damaged by the discharge phenomenon. Therefore, in the present embodiment, as illustrated in FIG. 2B, a neutralization brush 500 is provided so that the static electricity charged on the substrate P can be removed even during movement between the substrate holder 121 (first region) and the pedestal unit 204 (second region), more specifically, so that the static electricity guided from the substrate P and charged on the substrate tray 201 can be removed.

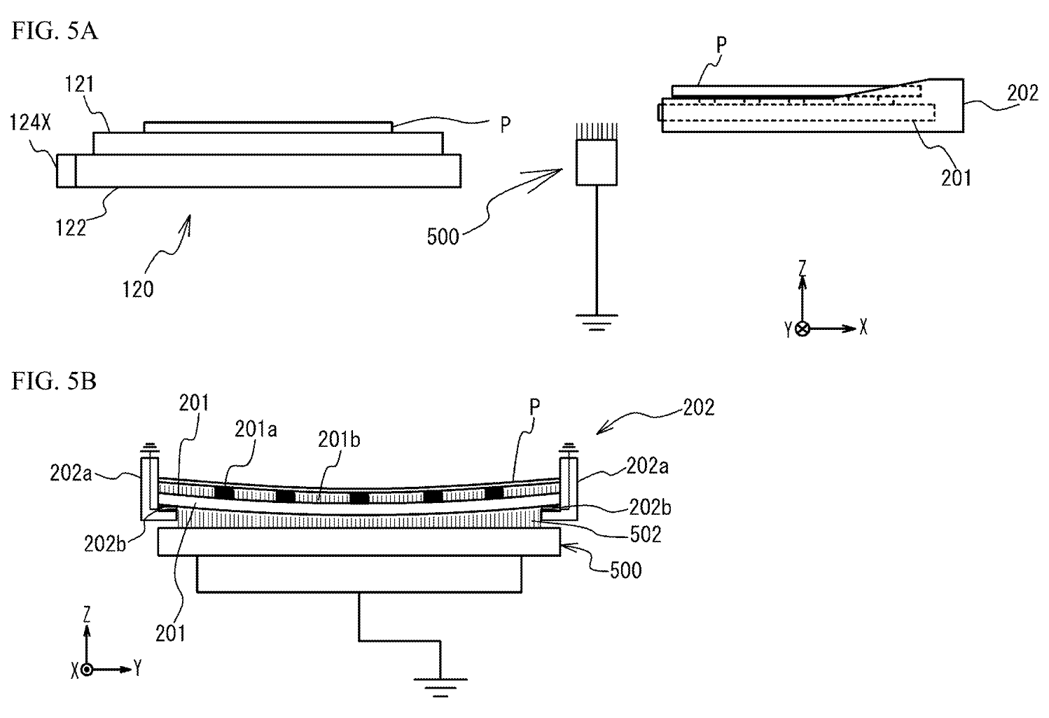

FIG. 5A is a diagram for describing a relationship among the substrate holder 121, the transfer mechanism 202, and the neutralization brush 500, and FIG. 5B is a diagram for describing a relationship between the neutralization brush 500 and the substrate tray 201.

As illustrated in FIG. 5A, the neutralization brush 500 is provided in a region between the main body 100 and the pedestal unit 204 in the X-axis direction. As illustrated in FIG. 5B, the neutralization brush 500 extends in a direction (Y-axis direction) orthogonal to the moving direction (X-axis direction) of the substrate tray 201. The neutralization brush 500 is provided so as to face the surface on the opposite side of the substrate tray 201, which is moving between the pedestal unit 204 and the substrate holder 121, from the surface holding the substrate P. The neutralization brush 500 is grounded.

The neutralization brush 500 has conductive bristle bundles 502 that extend toward the substrate tray 201 (extends in the +Z direction) when the substrate tray 201 is above the neutralization brush 500, and remove static electricity guided from the substrate P to the base member 201a of the substrate tray 201. Accordingly, while the transfer mechanism 202 transfers the substrate P between the pedestal unit 204 and the substrate holder 121, it is possible to inhibit devices such as TFTs formed on the substrate P from being damaged by the discharge phenomenon of the static electricity charged on the substrate P.

As illustrated in FIG. 5B, the neutralization brush 500 is provided so that the conductive bristle bundles 502 do not contact the lower surface of the base member 201a of the substrate tray 201 (the surface on the opposite side of the substrate tray 201 from the surface supporting the substrate P). The substrate tray 201 and the substrate P transferred by the transfer mechanism 202 are bent by their own weights. Accordingly, the central portions of the substrate tray 201 and the substrate P are positioned lower than both end portions in the Y-axis direction. Therefore, the conductive bristle bundles 502 of the neutralization brush 500 is short in length in the center portion in the Y-axis direction and becomes longer at closer distances to both end portions. This prevents the conductive bristle bundles 502 of the neutralization brush 500 from coming into contact with the substrate tray 201. If the conductive bristle bundles 502 come into contact with the substrate tray 201 and are worn, dust is generated in the exposure device EX due to the wear, and the dust may cause exposure failure. By setting the length of the conductive bristle bundles 502 of the neutralization brush 500 as described above, it is possible to inhibit the occurrence of exposure failure.

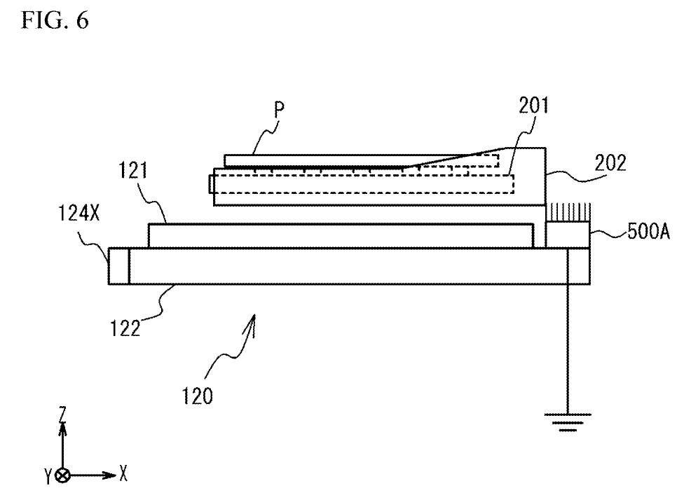

In addition to the neutralization brush 500 or instead of the neutralization brush 500, a grounded neutralization brush 500A may be provided on the substrate stage 122, as illustrated in FIG. 6. In this case as well, the neutralization brush 500A may be provided so as to extend in the direction (Y-axis direction) orthogonal to the movement direction (X-axis direction) of the substrate tray 201 and face the surface on the opposite side of the substrate tray 201, which is moving between the pedestal unit 204 and the substrate holder 121, from the surface holding the substrate P. In addition, to prevent contact with the substrate tray 201, the length of the conductive bristle bundles of the neutralization brush 500A is configured to be short in the center portion in the Y-axis direction and become longer at closer distances to both end portions.

The substrate P may be transferred to the substrate holder 121 by, for example, the fork-shaped robot hand RH illustrated in FIG. 2A, instead of the substrate tray 201. When the substrate P is transferred to the substrate holder 121 by the robot hand RH, the substrate transfer device 200 is omitted.

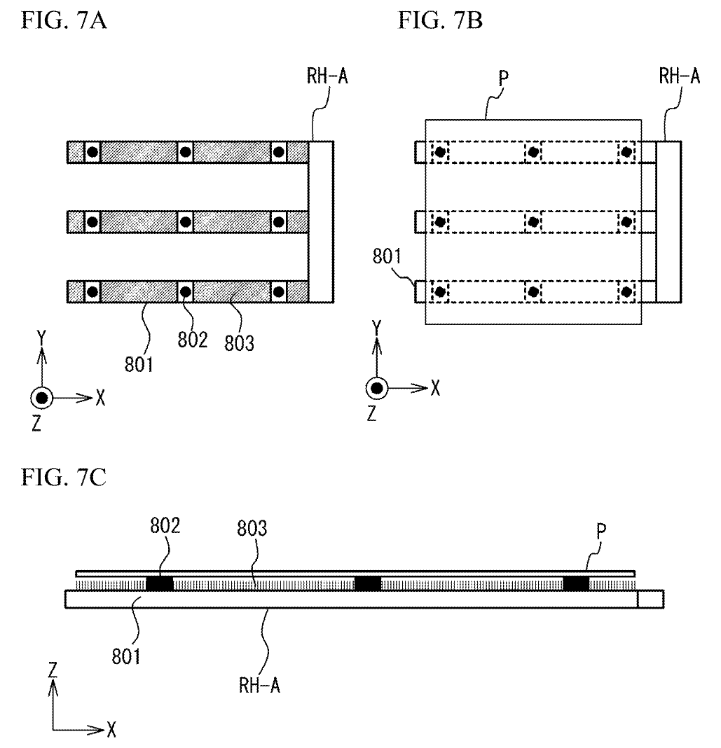

FIG. 7A to FIG. 7C are views for describing a robot hand RH-A according to a variation of the present embodiment. FIG. 7A is a view of the robot hand RH-A as viewed from the +Z direction, FIG. 7B is a view of the robot hand RH-A on which the substrate P is placed as viewed from the Y direction, and FIG. 7C is a view of the robot hand RH-A on which the substrate P is placed as viewed from the Y direction.

As illustrated in FIG. 7A and FIG. 7C, the robot hand RH-A includes a conductive base member 801, conductive support members 802 provided on the base member 801, and neutralization brushes 803. The support member 802 is electrically connected to the base member 801. The neutralization brush 803 has conductive bristle bundles, and the conductive bristle bundles are electrically connected to the base member 801. Accordingly, the static electricity charged on the substrate P is guided to the base member 801 via the support members 802 and the neutralization brushes 803.

The neutralization brush 500 is arranged on a path where the robot hand RH-A transfers the substrate P to the main body 100 and on a path where the substrate P is transferred from the main body 100 to a predetermined position. Accordingly, the static electricity guided to the base member 801 can be discharged to the ground via the neutralization brush 500. Therefore, it is possible to inhibit devices such as TFTs formed on the substrate P from being damaged by the discharge phenomenon of the static electricity charged on the substrate P.

The support member 802 may be non-conductive. Further, a discharge cable electrically connected to the base member 801 of the robot hand RH-A may be provided.

Mask loader 300

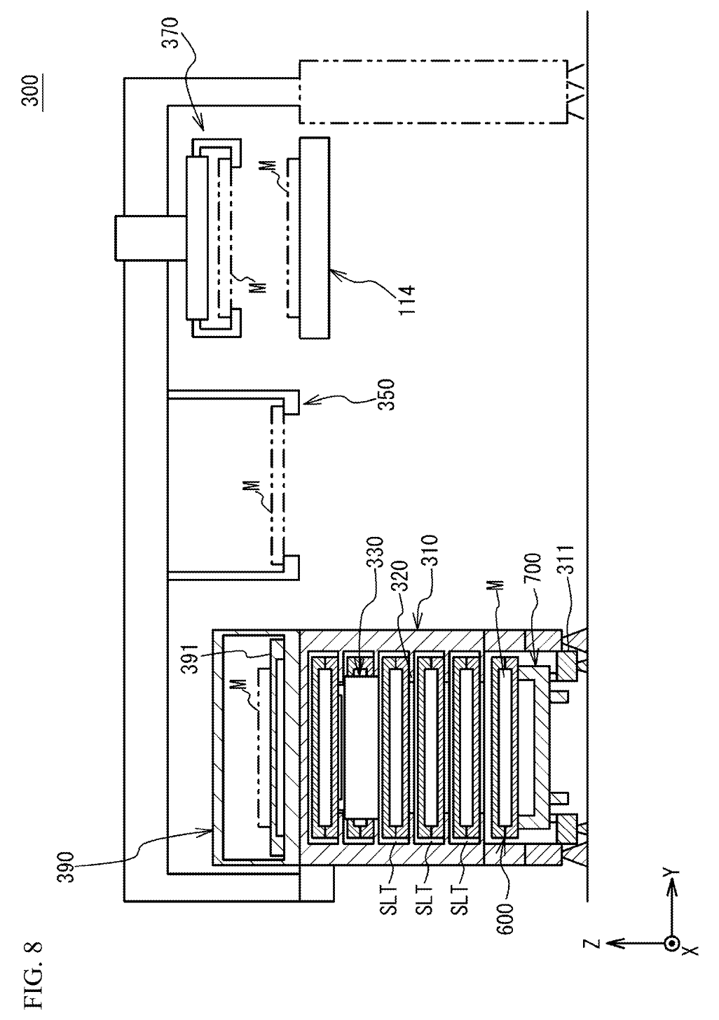

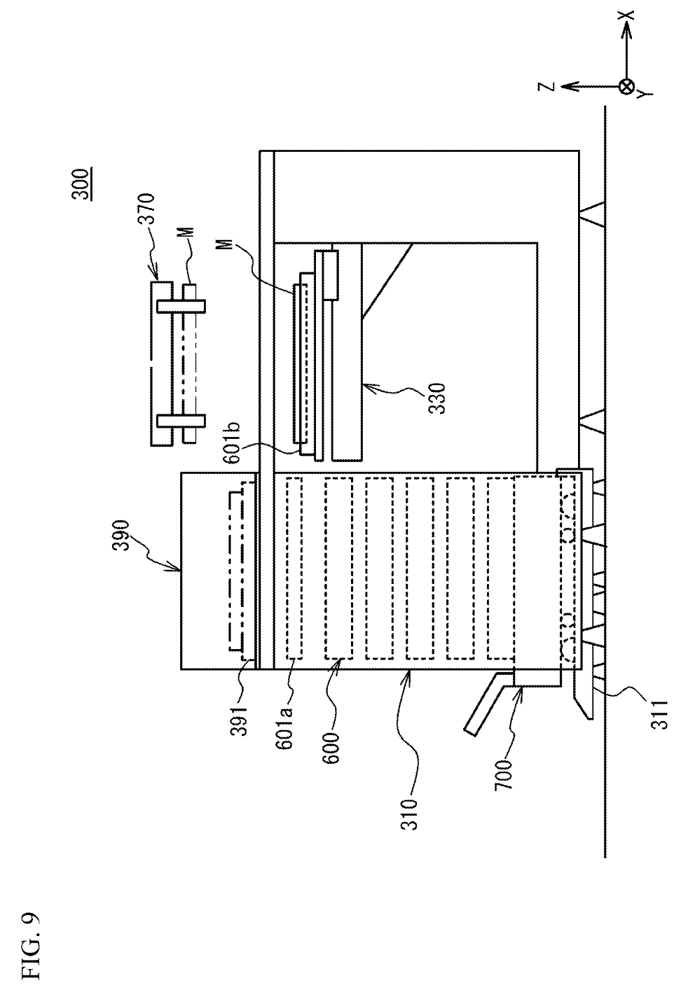

FIG. 8 and FIG. 9 are diagrams for describing a configuration of the mask loader 300. In FIG. 8, a part of the configuration is illustrated in a cross-sectional view.

As illustrated in FIG. 8 and FIG. 9, the mask loader 300 includes a mask buffer 310, a pellicle particle detection unit (hereinafter referred to as PPD) 390, a buffer arm 330, a relay table 350, and a mask transfer mechanism 370.

The mask buffer 310 temporarily stores the mask case 600 in which the mask M is accommodated. The mask buffer 310 has a plurality of slots SLT for storing the mask cases 600.

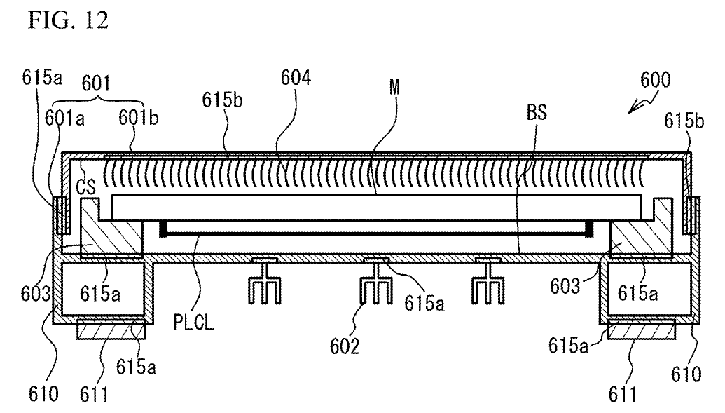

The PPD 390 is disposed on the top of the mask buffer 310. The PPD 390 inspects the presence or absence of a foreign substance adhering to a pellicle PLCL (see FIG. 12) of the mask M and the presence or absence of a foreign substance adhering to a surface on the opposite side of the mask M from the surface on which the pellicle PLCL is provided. The PPD 390 has a PPD arm 391.

The relay table 350 temporarily holds the mask M being transferred when the masks M are exchanged. The relay table 350 includes a table (not illustrated) for placing the mask M to be loaded on the mask stage 114 of the main body 100, and a table (not illustrated) for placing the mask M unloaded from the mask stage 114 of the main body 100.

The buffer arm 330 carries in and out the mask case 600 from the mask buffer 310 and carries it. The mask transfer mechanism 370 transfers the mask M from the relay table 350 to the main body 100, and conversely transfers the mask M from the main body 100 to the relay table 350. The mask transfer mechanism 370 transfers the mask M to the PPD arm 391 and receives the mask M from the PPD arm 391. The mask transfer mechanism 370 also delivers the mask M to the buffer arm 330.

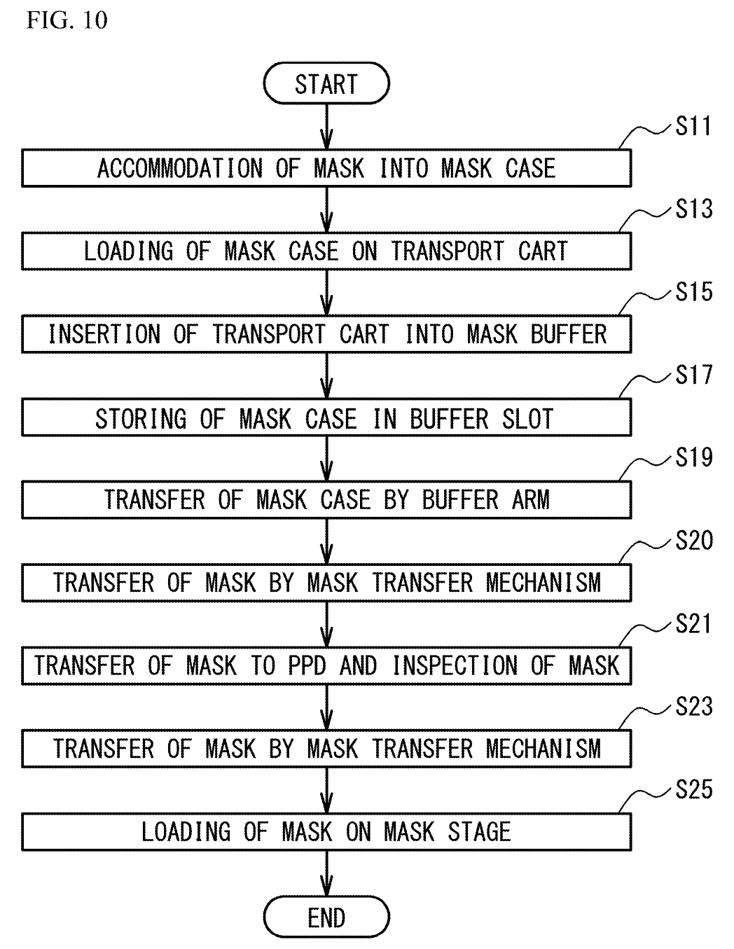

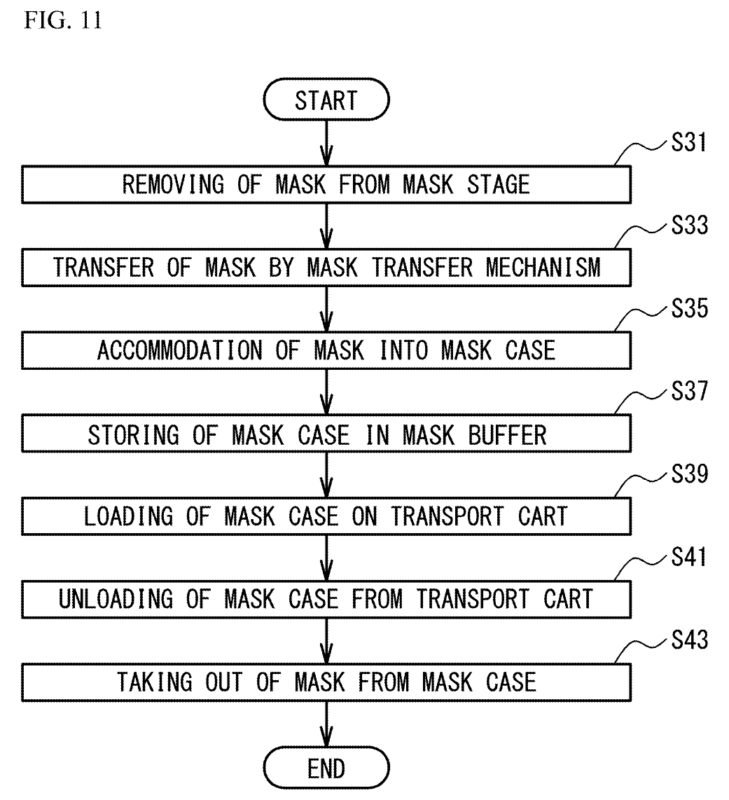

The process executed by the mask loader 300 will be described with reference to FIG. 10 and FIG. 11. FIG. 10 is a flowchart illustrating a series of processes until the mask M is mounted on the mask stage 114, and FIG. 11 is a flowchart illustrating a series of processes after the mask M is removed from the mask stage 114.

In the process illustrated in FIG. 10, first, the mask M on which a pattern is formed is accommodated in a mask case 600 to be described later (step S11). Then, the mask case 600 in which the mask M is accommodated is loaded on a transport cart 700 described later (step S13). The transport cart 700 on which the mask case 600 is placed is inserted into the mask buffer 310 (step S15). Thus, the mask case 600 is inserted into the mask buffer 310.

The mask case 600 inserted into the mask buffer 310 is stored in each slot SLT of the mask buffer 310 (step S17).

When the mask M accommodated in the mask case 600 stored in the mask buffer 310 is used, the mask M is transferred by the buffer arm 330 together with the mask case 600 (step S19).

The mask transfer mechanism 370 takes out the mask M from the mask case 600 transferred by the buffer arm 330 and transfers the mask M (step S20). The mask M is transferred to the PPD arm 391 of the PPD 390, and in the PPD 390, the presence or absence of a foreign substance adhering to the pellicle PLCL of the mask M and the presence or absence of a foreign substance adhering to the surface on the opposite side of the mask M from the surface on which the pellicle PLCL is provided are inspected (step S21).

When the inspection in the PPD 390 is completed, the mask M is transferred to the mask stage 114 via the relay table 350 by the mask transfer mechanism 370 (step S23). Thereafter, the mask M is loaded on the mask stage 114 (step S25), and the process of FIG. 10 is completed.

On the other hand, the process of FIG. 11 is started when the exposure of the substrate P is completed. First, the mask M is removed from the mask stage 114 (step S31).

Then, the removed mask M is transferred by the mask transfer mechanism 370 (step S33). The mask M transferred by the mask transfer mechanism 370 is accommodated in the mask case 600 (step S35).

The mask case 600 is transferred by the buffer arm 330 and stored in the mask buffer 310 (step S37).

The mask case 600 stored in the mask buffer 310 is taken out from the mask buffer 310 and then loaded on the transport cart 700 (step S39). The mask case 600 is transported to a predetermined place by the transport cart 700 and is unloaded from the transport cart 700 (step S41). The mask M is taken out from the mask case 600 unloaded from the transport cart 700 (step S43), and the process of FIG. 11 is completed.

In a series of processes related to the mask M illustrated in FIG. 10 and FIG. 11, when the mask M is carried into the PPD 390 (FIG. 10: step S21), when the mask M is loaded onto the mask stage 114 (FIG. 10: step S25), when the mask M is unloaded from the mask stage 114 (FIG. 11: step S31), and when the mask M is taken out from the mask case 600 (FIG. 11: step S43), static electricity charged on the mask M are conventionally removed by an X-ray ionizer or the like. In the present embodiment, the static electricity charged on the mask M is eliminated also in the other steps, thereby further inhibiting the pattern formed on the mask M from being damaged by the discharge phenomenon of the static electricity.

Mask case 600

Next, the mask case 600 according to the present embodiment will be described. FIG. 12 is a cross-sectional view for describing the structure of the mask case 600. In FIG. 12, hatching of some elements is omitted.

As illustrated in FIG. 12, the mask case 600 includes a case body 601 that accommodates the mask, and a discharge cable 602.

The case body 601 includes a first case portion 601a having a bottom surface BS, and a second case portion 601b that is detachably provided relative to the first case portion 601a and has a ceiling surface CS to be arranged to face the bottom surface BS. The first case portion 601a and the second case portion 601b are electrically conductive.

The first case portion 601a has leg portions 610, and mask case support portions 611 are attached to the leg portions 610, respectively. The mask case support portion 611 is electrically conductive and is electrically connected to the first case portion 601a (leg portion 610).

Mask support members 603 for supporting the mask M are provided on the bottom surface BS of the first case portion 601a. The mask support members 603 support the mask M so that the pellicle PLCL protecting a region of the mask M where a pattern is formed does not contact the bottom surface BS. The mask support members 603 are electrically conductive and are electrically connected to the first case portion 601a. Therefore, the mask support members 603 and the mask case support portion 611 are electrically connected to each other.

The discharge cable 602 is electrically connected to the first case portion 601a. Therefore, the mask support members 603 and the discharge cables 602 are electrically connected to each other. Accordingly, the static electricity on the mask M is guided to the conductive first case portion 601a by the mask support member 603, and the static electricity charged on the first case portion 601a is discharged by the discharge cable 602. This makes it possible to inhibit the pattern formed on the mask M from being damaged by the discharge phenomenon of the static electricity charged on the mask M.

A neutralization brush 604 having conductive bristle bundles is provided on the ceiling surface CS of the second case portion 601b. The neutralization brush 604 is electrically connected to the second case portion 601b. The neutralization brush 604 faces the mask M supported by the mask support members 603, and guides the static electricity charged on the mask M to the second case portion 601b.

In a state where the second case portion 601b is attached to the first case portion 601a, the first case portion 601a and the second case portion 601b are electrically connected to each other. Accordingly, the static electricity guided from the mask M to the second case portion 601b is guided to the discharge cables 602 by the first case portion 601a and discharged from the discharge cables 602. This makes it possible to inhibit the pattern formed on the mask M from being damaged by the discharge phenomenon of the static electricity charged on the mask M.

The first case portion 601a and the second case portion 601b are made of, for example, aluminum, and a non-conductive coating film (a rust prevention film or the like) is formed on the surfaces thereof. Therefore, in the present embodiment, in a state where the second case portion 601b is attached to the first case portion 601a, the coating film of the portion where the first case portion 601a and the second case portion 601b are in contact with each other is removed. In addition, in the first case portion 601a, the coating film of the portion to which the mask support member 603 is attached is removed. In addition, in the first case portion 601a, the coating film of the portion to which the mask case support portion 611 is attached is removed. Additionally, in the second case portion 601b, the coating film of the portion where the neutralization brush 604 is disposed is removed. This ensures electrical connection. In FIG. 12, the portion of the first case portion 601a from which the coating film is removed is indicated as a coating removed region 615a, and the portion of the second case portion 601b from which the coating film is removed is indicated as a coating removed region 615b.

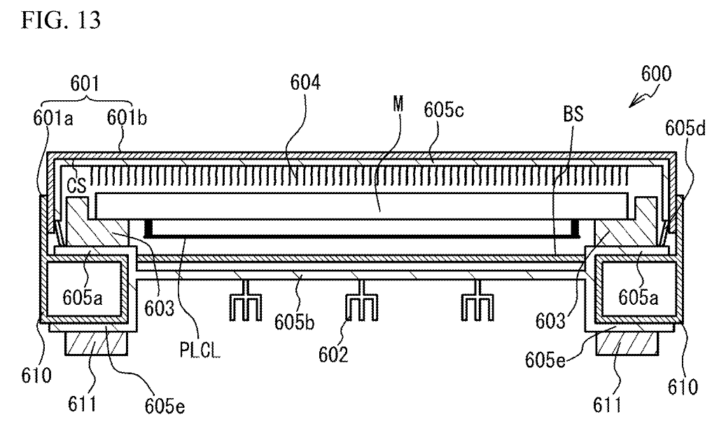

Instead of removing the coating film, a conductive electrode member such as a bus bar may be provided. FIG. 13 is a cross-sectional view illustrating another configuration example of the mask case 600.

In the mask case 600 illustrated in FIG. 13, an electrode member 605a such as a bus bar is provided on a part of the bottom surface BS of the first case portion 601a, and the mask support members 603 are electrically connected to the electrode member 605a. In addition, an electrode member 605b such as a bus bar is provided to electrically connect the electrode member 605a provided in the first case portion 601a and the discharge cables 602.

In addition, an electrode member 605c such as a bus bar is provided on the ceiling surface CS of the second case portion 601b, and the neutralization brush 604 is electrically connected to the electrode member 605c. An electrode member 605d, such as a bus bar, is provided to electrically connect the electrode member 605c and the electrode member 605a in a state where the second case portion 601b is attached to the first case portion 601a. The electrode member 605d is elastic, thereby ensuring a reliable electrical connection between the electrode member 605c and the electrode member 605a.

Additionally, an electrode member 605e, such as a bus bar, is provided on the leg portion 610 of the first case portion 601a, and the mask case support portion 611 is electrically connected to the electrode member 605e. In this manner, the electrode members may be used to establish electrical connections between the members, and static electricity charged on the mask M may be discharged from the discharge cables 602.

The mask case 600 accommodating the mask M is transported to the mask buffer 310 by the transport cart 700 and stocked in the mask buffer 310.

Transport cart 700

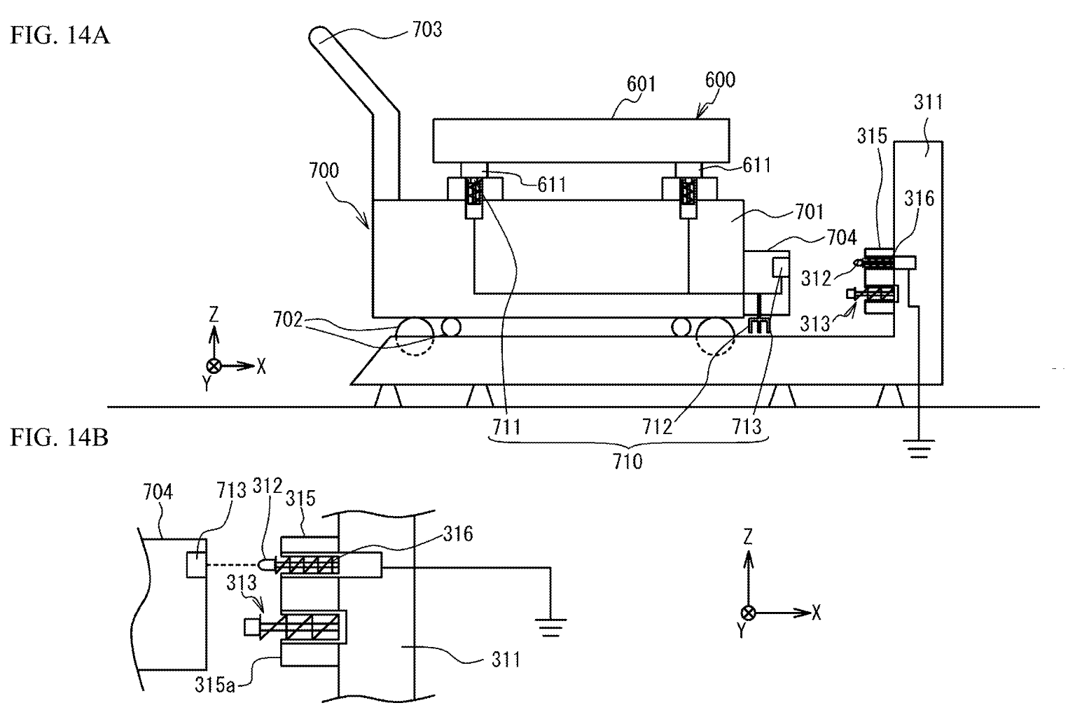

FIG. 14A illustrates an overview of the transport cart 700. As illustrated in FIG. 14A, the transport cart 700 includes a placement portion 701 on which the mask case 600 is placed, wheels 702 attached to the placement portion 701, a handle portion 703 gripped by an operator when the transport cart 700 is moved, and a mechanical stopper 704 disposed on the front side of the placement portion 701. The transport cart 700 further includes a neutralization mechanism 710 that eliminates static electricity charged on the mask case 600 placed on the placement portion 701.

The neutralization mechanism 710 includes first electrode components 711, a discharge cable 712, and an electrode member 713.

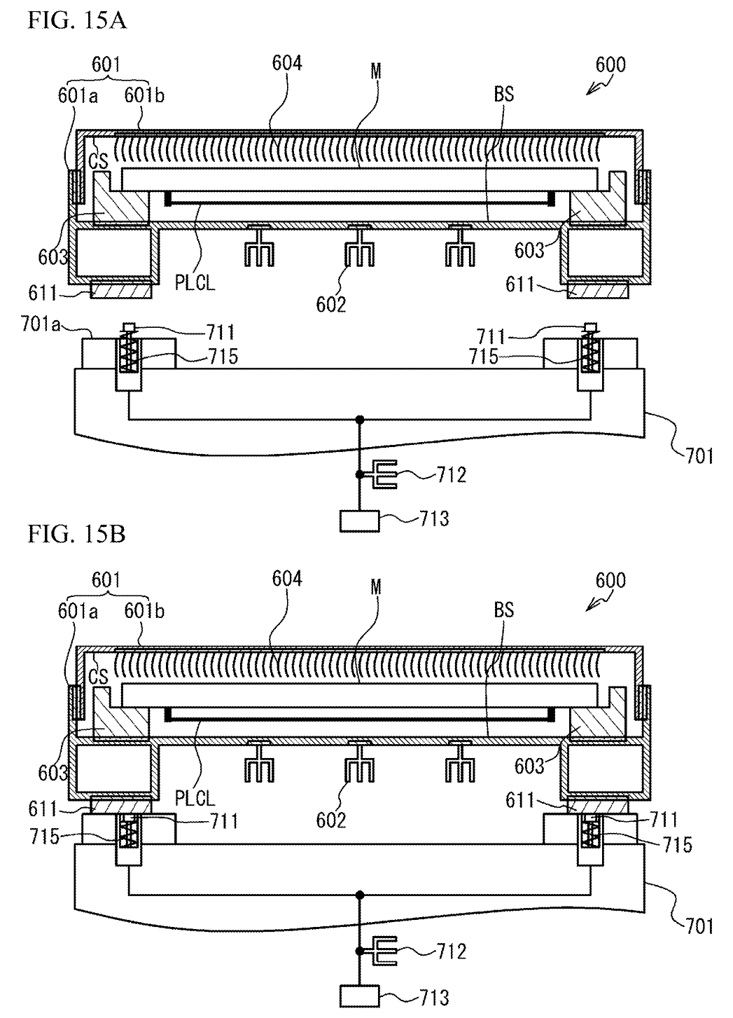

FIG. 15A and FIG. 15B are diagrams for describing the structure of the neutralization mechanism 710.

The first electrode component 711 is, for example, a contact probe, and is biased upward by a biasing member 715 such as a compression spring as illustrated in FIG. 15A. Accordingly, the tip of the first electrode component 711 protrudes beyond a contact surface 701a, which contacts the mask case support portions 611 of the mask case 600, of the placement portion 701.

As illustrated in FIG. 15B, when the mask case 600 is placed on the placement portion 701, the first electrode components 711 and the mask case support portions 611 come into contact with each other and are electrically connected to each other.

The first electrode components 711 are electrically connected to the discharge cable 712. Accordingly, static electricity charged on the mask case 600 can be guided to the discharge cable 712 by the first electrode components 711 and discharged from the discharge cable 712. This inhibits the pattern formed on the mask M from being damaged by the discharge phenomenon of static electricity charged on the mask M during transport of the mask case 600, in which the mask M is accommodated, by the transport cart 700.

The first electrode components 711 are electrically connected to the electrode member 713 provided on the front side of the mechanical stopper 704. The electrode member 713 is a conductive member, and is, for example, a bus bar.

As illustrated in FIG. 9, when the mask case 600 is stored in the mask buffer 310, the transport cart 700 is positioned by riding onto a positioning frame 311 of the mask buffer 310. As illustrated in FIG. 14A, the positioning frame 311 includes a mechanical stopper 315. The mechanical stopper 704 of the transport cart 700 comes into contact with the mechanical stopper 315 of the positioning frame 311, whereby the transport cart 700 is positioned in the positioning frame 311.

FIG. 14B is an enlarged view of the mechanical stopper 315. The mechanical stopper 315 includes a second electrode component 312 and an impact absorbing component 313 such as a shock absorber.

The impact absorbing component 313 absorbs the impact caused when the mechanical stopper 704 of the transport cart 700 comes into contact with the mechanical stopper 315.

The second electrode component 312 is, for example, a contact probe, and is electrically connected to the electrode member 713 of the transport cart 700 when the transport cart 700 is positioned on the positioning frame 311. In the present embodiment, the second electrode component 312 is biased by a biasing member 316 such as a compression spring so that the tip of the second electrode component 312 protrudes beyond a mechanical stopper surface 315a. This ensures that even when the transport cart 700 is pushed back by the reaction force of the impact absorbing component 313 when the mechanical stopper 315 and the mechanical stopper 704 come into contact and the transport cart 700 stops, the contact (electrical connection) between the second electrode component 312 and the electrode member 713 can be maintained.

The second electrode component 312 is grounded. Therefore, when the transport cart 700 is positioned on the positioning frame 311, static electricity charged on the mask case 600 can be released to the ground via the first electrode component 711, the electrode member 713, and the second electrode component 312. This inhibits the pattern formed on the mask M from being damaged by the discharge phenomenon of static electricity.

When the transport cart 700 is positioned by the positioning frame 311, the mask case 600 placed on the placement portion 701 is carried into the mask buffer 310.

Mask buffer 310

As illustrated in FIG. 8, the mask buffer 310 includes a plurality of slots SLT in which the mask cases 600 are stored, respectively, and a shelf portion 320 on which the mask case 600 is placed is provided in each slot SLT.

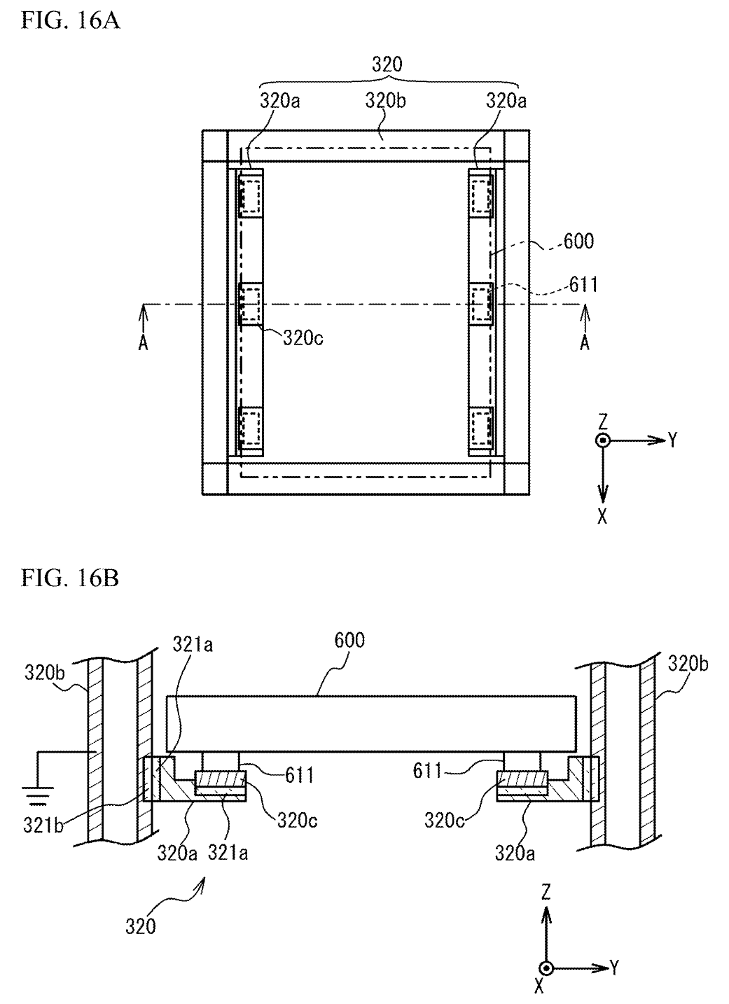

FIG. 16A and FIG. 16B are diagrams for describing the configuration of each shelf portion 320, where FIG. 16A is a schematic diagram of the shelf portion 320 of the mask buffer 310 as viewed from the +Z direction, and FIG. 16B is a cross-sectional view taken along line A-A in FIG. 16A.

As illustrated in FIG. 16A and FIG. 16B, the shelf portion 320 includes a pair of support portions 320a that support the mask case 600, and a frame portion 320b to which the support portions 320a are fixed.

The pair of support portions 320a are disposed to be spaced apart from each other in the Y-axis direction, and each support portion 320a extends in the X-axis direction. Each support portion 320a includes a plurality of case support members 320c that contact the mask case support portions 611 of the first case portion 601a of the mask case 600, respectively, and support the mask case 600 from below.

The support portions 320a, the frame portion 320b, and the case support members 320c have conductivity. The support portions 320a and the frame portion 320b are electrically connected to each other, and the case support members 320c and the support portions 320a are electrically connected to each other. Accordingly, the case support members 320c and the frame portion 320b are electrically connected to each other. In the present embodiment, a non-conductive coating film (for example, a rust prevention coating film or the like) is formed on the surfaces of the support portions 320a and the frame portion 320b. Therefore, the coating film of the portion for electrical connection is removed from the support portions 320a and the frame portion 320b. In FIG. 16B, the portion of the support portion 320a from which the coating film is removed is indicated as a coating removed region 321a, and the portion of the frame portion 320b from which the coating film is removed is indicated as a coating removed region 321b.

The frame portion 320b is grounded. When the mask case 600 is placed on the shelf portion 320, the static electricity charged on the mask case 600 is guided to the frame portion 320b via the case support members 320c and the support portion 320a, and is released to the ground. This inhibits the pattern formed on the mask M from being damaged by the discharge phenomenon of static electricity charged on the mask case 600 and the mask M accommodated in the mask case 600. That is, in the mask buffer 310, the case support members 320c that are in contact with the mask case 600, the support portions 320a that are electrically connected to the case support members 320c, and the frame portion 320b that is electrically connected to the support portions 320a and is grounded function as a neutralization mechanism that eliminates static electricity charged on the mask case 600.

For example, a neutralization brush having conductive bristle bundles extending toward the mask case 600 may be provided on a surface (+Z-side surface) of the support portion 320a facing the mask case 600. In this case, the conductive bristle bundles are electrically connected to the support portions 320a. This allows the neutralization brush to guide the static electricity charged on the mask case 600 to the frame portion 320b. When the neutralization brush is provided, the case support members 320c may be non-conductive.

Buffer arm 330

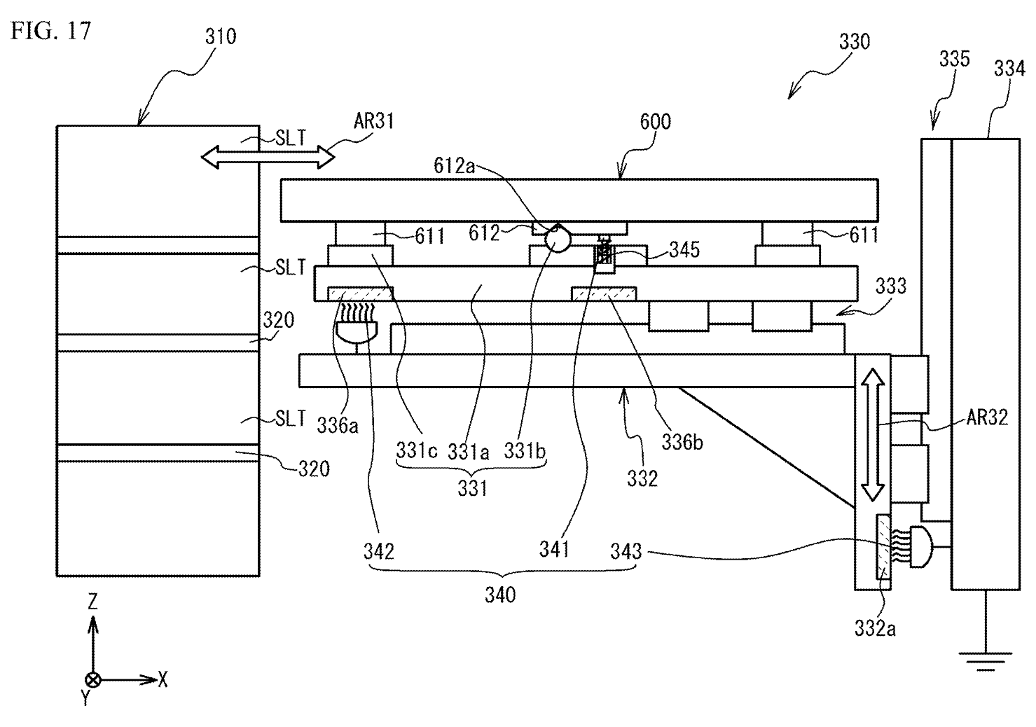

The mask cases 600 stocked in the mask buffer 310 are carried in and out by the buffer arm 330. FIG. 17 is a schematic view illustrating the configuration of the buffer arm 330. The buffer arm 330 includes an arm portion 331 that is driven in the X-axis direction to take out the mask case 600 from the mask buffer 310 (more specifically, the shelf portion 320) and insert the mask case 600 into the mask buffer 310, and a neutralization mechanism 340 that eliminates static electricity charged on the arm portion 331.

The arm portion 331 includes a conductive main body portion 331a, a positioning mechanism 331b, and pedestal portions 331c. The pedestal portions 331c support the mask case support portions 611 of the mask case 600. The positioning mechanism 331b engages with a recessed portion 612a of a positioning portion 612 of the mask case 600, and determines the position of the mask case 600 with respect to the buffer arm 330 so that the mask case support portions 611 are supported by the pedestal portions 331c. The positioning portion 612 has conductivity and is electrically connected to the first case portion 601a of the mask case 600.

The arm portion 331 is driven in the X-axis direction as indicated by an arrow AR31 by a first driving mechanism 333 such as a linear guide held by a conductive first frame 332. This allows the arm portion 331 to enter the slot SLT. The first frame 332 is driven in the Z-axis direction as indicated by an arrow AR32 by a second driving mechanism 335 such as a linear guide held by a conductive second frame 334. This enables the mask case 600 to be removed from each of the slots SLT located at different positions along the Z-axis. When the mask M is taken out from the slot SLT, the second case portion 601b remains in the slot SLT, and only the first case portion 601a in which the mask M is accommodated is taken out by the arm portion 331.

The neutralization mechanism 340 includes a third electrode component 341, a first neutralization brush 342, and a second neutralization brush 343.

The third electrode component 341 is, for example, a contact probe, and comes into contact with the mask case 600 (the positioning portion 612) when the mask case 600 is placed on the arm portion 331. This electrically connects the mask case 600 and the third electrode component 341. The third electrode component 341 is biased by a biasing member 345 such as a compression spring so that the tip of the third electrode component 341 is positioned above the position where the positioning portion 612 of the mask case 600 is present when the mask case 600 is placed on the arm portion 331. This ensures more reliable electrical contact between the mask case 600 and the third electrode component 341. The third electrode component 341 is electrically connected to the main body portion 331a. This allows the static electricity charged on the mask case 600 to be guided to the main body portion 331a.

The first neutralization brush 342 has conductive bristle bundles extending toward the main body portion 331a. The first neutralization brush 342 is electrically connected to the first frame 332. In the present embodiment, a non-conductive coating film is formed on the surface of the main body portion 331a of the arm portion 331, but the coating film is removed from the portion indicated by the dotted hatching in FIG. 17. Specifically, the coating film is removed from the lower surface of the -X-side end portion and the lower surface near the central portion of the main body portion 331a, and the material of the main body portion 331a is exposed. When the region where the coating film is removed on the lower surface of the -X-side end portion is defined as a coating removed region 336a and the region where the coating film is removed on the lower surface near the central portion is defined as a coating removed region 336b, the first neutralization brush 342 can guide the static electricity charged on the main body portion 331a to the first frame 332 when facing the coating removed region 336a and the coating removed region 336b. In other words, the first neutralization brush 342 guides the static electricity charged on the main body portion 331a (the arm portion 331) to the first frame 332 when the arm portion 331 is located closest to the mask buffer 310 in the X-axis direction and when the arm portion 331 is located closest to the second frame 334 in the X-axis direction.

The second neutralization brush 343 has conductive bristle bundles extending toward the first frame 332. The second neutralization brush 343 is electrically connected to the second frame 334. In the present embodiment, a non-conductive coating film is formed on the surface of the first frame 332, but the coating film is removed from the portion indicated by the dotted hatching in FIG. 17. Specifically, the coating film is removed in the -Z-side end portion of the first frame 332, and the material of the first frame 332 is exposed. When a region of the first frame 332 where the coating film is removed is defined as a coating removed region 332a, the second neutralization brush 343 can guide the static electricity charged on the first frame 332 to the second frame 334 when facing the coating removed region 332a. Although FIG. 17 illustrates one second neutralization brush 343, in the present embodiment, the second neutralization brush 343 is provided at least at two locations so as to face the coating removed region 332a of the first frame 332 when the first frame 332 is located at the highest position in the Z-axis direction and when the first frame 332 is located at the lowest position in the Z-axis direction.

The second neutralization brush 343 may be provided so as to face the coating removed region 332a of the first frame 332 at least at one of the following timings: when the first frame 332 is at the highest position in the Z-axis direction and when the first frame 332 is at the lowest position in the Z-axis direction. The second neutralization brushes 343 may be provided at a plurality of locations spaced apart from each other in the Z-axis direction so as to correspond to the stop positions of the arm portion 331 in the Z-axis direction (positions corresponding to the respective slots SLT).

The second frame 334 is grounded. This allows the static electricity charged on the mask case 600 to be discharged to the ground via the third electrode component 341, the main body portion 331a, the first neutralization brush 342, the first frame 332, the second neutralization brush 343, and the second frame 334. As described above, the first neutralization brush 342 guides the static electricity charged on the main body portion 331a (the arm portion 331) to the first frame 332 when the arm portion 331 is located closest to the mask buffer 310 in the X-axis direction and when the arm portion 331 is located closest to the second frame 334 in the X-axis direction. Therefore, when the mask case 600 is taken out from the shelf portion 320, and when the mask case 600 is returned to the shelf portion 320, the static electricity charged on the mask case 600 can be eliminated.

The mask M accommodated in the first case portion 601a carried to the predetermined position in the Z-axis direction by the buffer arm 330 is taken out from the mask case 600 (the first case portion 601a) by the mask transfer mechanism 370. The PPD arm 391 moves to a position below the mask transfer mechanism 370, and the mask M is transferred from the mask transfer mechanism 370 to the PPD arm 391. The PPD arm 391 with the mask M thereon moves into the PPD 390. In the PPD 390, the presence or absence of a foreign substance adhering to the pellicle PLCL of the mask M and the presence or absence of a foreign substance adhering to the surface on the opposite side of the mask M from the surface on which the pellicle PLCL is provided are inspected. The PPD arm 391 on which the mask M for which the foreign substance inspection has been completed is placed moves to below the mask transfer mechanism 370, and the mask M is transferred from the PPD arm 391 to the mask transfer mechanism 370.

The mask transfer mechanism 370 holding the mask M moves the mask M to the mask stage 114 of the main body 100.

Mask transfer mechanism 370

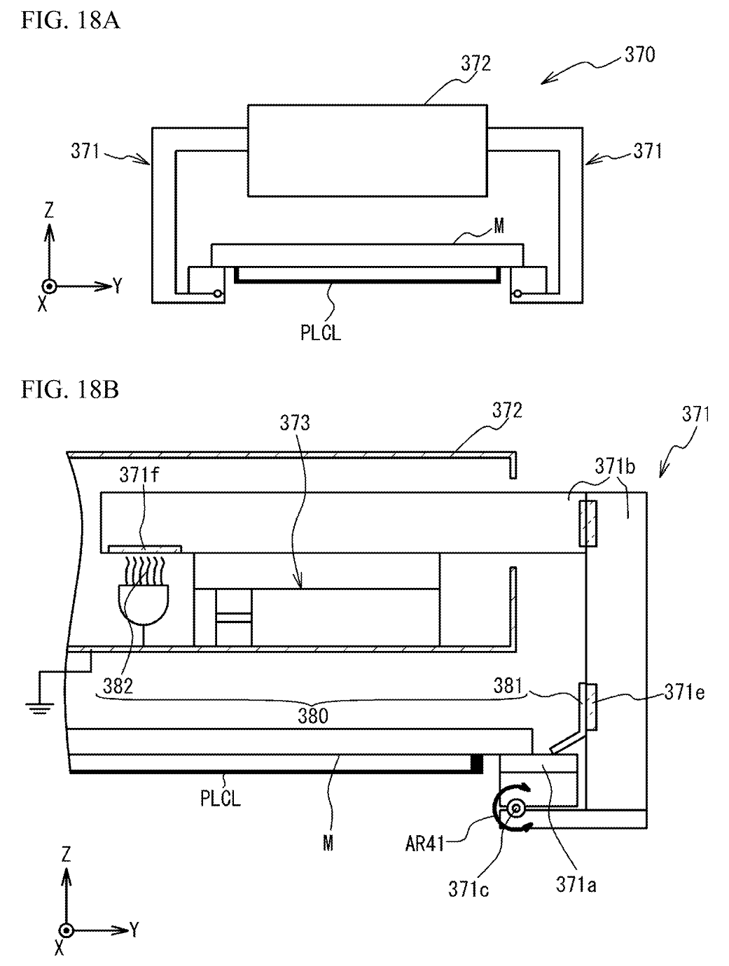

FIG. 18A illustrates an external appearance of the mask transfer mechanism 370 according to the present embodiment, and FIG. 18B is a schematic diagram illustrating a configuration of the mask transfer mechanism 370. As illustrated in FIG. 18A and FIG. 18B, the mask transfer mechanism 370 includes a pair of holding portions 371 that hold the mask M, and a neutralization mechanism 380 that eliminates static electricity charged on the holding portions 371. FIG. 18B illustrates one of the pair of holding portions 371.

The holding portion 371 includes a conductive support portion 371a that comes into contact with the mask M and supports the mask M, and an arm portion 371b to which the support portion 371a is connected and which can be driven in the Y-axis direction. A part of the arm portion 371b is housed in a housing 372. The arm portion 371b is driven in the Y-axis direction by an actuator 373 such as a guided cylinder. The actuator 373 is also housed in the housing 372.

The support portion 371a and the arm portion 371b are electrically conductive. The neutralization mechanism 380 includes a connecting portion 381 that electrically connects the support portion 371a and the arm portion 371b and guides the static electricity charged on the support portion 371a to the arm portion 371b, and a neutralization brush 382 that guides the static electricity charged on the arm portion 371b to the housing 372.

In the present embodiment, the support portion 371a is rotatable about a shaft 371c as indicated by an arrow AR41. Therefore, the connecting portion 381 is elastic so as to ensure the electrical connection between the support portion 371a and the arm portion 371b. As the connection portion 381, for example, a metal plate spring can be used. The arm portion 371b has a conductive coating film on the surface of its conductive member, but the coating film is removed from a portion 371e to which the connecting portion 381 is connected. This allows the connection portion 381 to guide static electricity charged on the support portion 371a to the arm portion 371b.

Further, for example, the coating film is removed from a portion 371f of the arm portion 371b facing the neutralization brush 382 when the support portion 371a is holding the mask M. This allows static electricity charged on the arm portion 371b to be guided to the housing 372 when the support portion 371a is holding the mask M.

The housing 372 has conductivity and is grounded. Therefore, while the mask transfer mechanism 370 transports the mask M, the static electricity charged on the mask M can be guided to the housing 372 via the support portion 371a, the arm portion 371b, and the neutralization brush 382, and can be released from the housing 372 to the ground. This inhibits the pattern formed on the mask M from being damaged by the discharge phenomenon of static electricity charged on the mask M. When the arm portion 371b is formed of a plurality of members, the coating film is removed at the connection portions of the plurality of members to achieve electrical connection.

As described above in detail, according to the present embodiment, the exposure device EX includes the neutralization brush 500 that eliminates static electricity charged on the substrate tray 201 while the substrate tray 201 supporting the substrate P moves. The substrate tray 201 has the conductive base member 201a, the neutralization brush 210a facing the substrate P supported by the substrate tray 201 and guiding the static electricity charged on the substrate P to the base member 201a, and the conductive support member 201b, and the neutralization brush 500 eliminates the static electricity guided to the base member 201a. This inhibits the destruction of devices such as TFTs formed on the substrate P due to the discharge phenomenon of static electricity charged on the substrate P while the substrate P is transported using the substrate tray 201.

In addition, in the present embodiment, the neutralization brush 500 is provided in a region positioned between the main body 100 that performs static elimination on the substrate P and the pedestal unit 204, and eliminates static electricity charged on the substrate tray 201 while the substrate tray 201 moves through the region. In the present embodiment, the substrate P placed on the substrate holder 121 is eliminated by the X-ray ionizer provided in the main body 100, but when the neutralization brush 500 is not provided, there is no means for releasing the static electricity charged on the substrate P (static electricity charged on the substrate tray 201) while the substrate P is transported between the main body 100 and the pedestal unit 204, and there is a concern that devices such as TFTs formed on the substrate P may be destroyed by a discharge phenomenon of the static electricity charged on the substrate P. By providing the neutralization brush 500 in the region positioned between the main body 100 and the pedestal unit 204, it is possible to eliminate static electricity guided from the substrate P to the substrate tray 201 while the substrate P is transported between the main body 100 and the pedestal unit 204, and thus it is possible to inhibit the destruction of devices such as TFTs formed on the substrate P due to the discharge phenomenon of static electricity charged on the substrate P.

In addition, in the present embodiment, the neutralization brush 500 is provided so as to face the surface on the opposite side of the substrate tray 201 from the surface holding the substrate P. Since the surface of the substrate tray 201 holding the substrate P is covered with the substrate P, even if the neutralization brush 500 is provided so as to face the surface holding the substrate P, there is a possibility that the static electricity charged on the substrate tray 201 cannot be sufficiently eliminated. By providing the neutralization brush 500 so as to face the surface on the opposite side of the substrate tray 201 from the surface holding the substrate P, static electricity charged on the substrate tray 201 can be eliminated more reliably compared to the case where the neutralization brush 500 is provided so as to face the surface holding the substrate P.

In the present embodiment, the neutralization brush 500 does not contact the substrate tray 201. When the neutralization brush 500 comes into contact with the substrate tray 201 and wears down, dust is generated in the exposure device EX due to the wear, and the dust may cause an exposure failure. Since the neutralization brush 500 does not contact the substrate tray 201, it is possible to inhibit the generation of dust in the exposure device EX due to wear and the occurrence of exposure defects due to the dust.

The neutralization brush 500 extends in a direction (Y-axis direction) intersecting the moving direction (X-axis direction) of the substrate tray 201. This makes it possible to reduce the area occupied by the neutralization brush 500 in the X-axis direction, and therefore, it is possible to eliminate the static electricity charged on the substrate tray 201 without increasing the size of the exposure device EX.

In the present embodiment, the substrate tray 201 includes the discharge cable 210b electrically connected to the base member 201a. Accordingly, even at a timing when the static electricity charged on the substrate tray 201 cannot be eliminated by the neutralization brush 500, the static electricity charged on the substrate tray 201 can be discharged into the air by the discharge cable 210b.

Further, according to the present embodiment, the substrate tray 201 is the substrate tray 201 that supports the substrate P to be moved, and includes the conductive base member 201a, the neutralization brush 210a that faces the substrate P and guides the static electricity charged on the substrate P to the base member 201a, and the discharge cable 210b electrically connected to the base member 201a. This allows static electricity charged on the substrate P to be guided to the base member 201a via the neutralization brush 210a and discharged through the discharge cable 210b while the substrate P is supported on the substrate tray 201. Therefore, it is possible to inhibit the destruction of devices such as TFTs formed on the substrate P due to the discharge phenomenon of the static electricity charged on the substrate P.

Furthermore, according to the present embodiment, the mask case 600 includes the case body 601 that is at least partially conductive and accommodates the mask M, the mask support members 603 and the neutralization brush 604 that guide static electricity charged on the mask M to the conductive portion of the case body 601, and the discharge cable 602 that is electrically connected to the conductive portion and eliminates static electricity charged on the conductive portion. Accordingly, while the mask M is accommodated in the mask case 600 (step S11 in FIG. 10, step S35 in FIG. 11, and step S41 in FIG. 11), the static electricity charged on the mask M can be guided to the case body 601 by the mask support member 603 and the neutralization brush 604 and discharged by the discharge cable 602, and thus, it is possible to inhibit the pattern formed on the mask M from being damaged by the discharge phenomenon of the static electricity charged on the mask M.

In the present embodiment, the case body 601 includes the first case portion 601a having the bottom surface BS, and the second case portion 601b that is detachably provided on the first case portion 601a and has the ceiling surface CS disposed to face the bottom surface BS. The first case portion 601a has conductivity, and the mask support member 603 is provided on the bottom surface BS so as to face the mask M, and guides the static electricity charged on the mask M to the first case portion 601a. The discharge cable 602 is provided to the outer side of the first case portion 601a and eliminates (discharges) the static electricity charged on the first case portion 601a. Accordingly, while the mask M is accommodated in the mask case 600, the static electricity charged on the mask M can be guided to the first case portion 601a by the mask support member 603 and discharged by the discharge cable 602, and thus, it is possible to inhibit the pattern formed on the mask M from being damaged by the discharge phenomenon of the static electricity charged on the mask M.

In the present embodiment, the second case portion 601b has conductivity, and the neutralization brush 604 is provided on the ceiling surface CS of the second case portion 601b, faces the mask M, and guides the static electricity charged on the mask M to the second case portion 601b. The first case portion 601a and the second case portion 601b are electrically connected to each other in a state where the second case portion 601b is attached to the first case portion 601a. This allows the static electricity charged on the mask M to be guided to the second case portion 601b by the neutralization brush 604, and discharged, by the discharge cable 602, from the second case portion 601b via the first case portion 601a.

In the present embodiment, the transport cart 700 that transports the mask case 600 includes the placement portion 701 on which the mask case 600 is placed, and the neutralization mechanism 710 that eliminates static electricity charged on the mask case 600 placed on the placement portion 701. This allows the static electricity charged on the mask case 600 to be eliminated while the mask case 600 is being transported (step S13 in FIG. 10 and step S39 in FIG. 11), and therefore, it is possible to inhibit the pattern formed on the mask M accommodated in the mask case 600 from being damaged by the discharge phenomenon of the static electricity.

In the present embodiment, the neutralization mechanism 710 includes the first electrode component 711 electrically connected to the conductive portion (the mask case support portion 611) of the mask case 600, and the discharge cable 712 that is electrically connected to the first electrode component 711 and eliminate static electricity charged on the mask case 600. Accordingly, while the mask case 600 is being transported, static electricity charged on the mask case 600 can be discharged by the discharge cable 712.

In addition, in the present embodiment, the neutralization mechanism 710 includes the electrode member 713 electrically connected to the first electrode component 711, and the electrode member 713 is electrically connected to the second electrode component 312 that is disposed on the positioning frame 311 and is grounded when the transport cart 700 is positioned on the positioning frame 311. Accordingly, when the transport cart 700 is positioned on the positioning frame 311 (step S15 in FIG. 10), the static electricity charged on the mask case 600 can be released to the ground.

In addition, in the present embodiment, the mask buffer 310 capable of stocking a plurality of the mask cases 600 includes the shelf portion 320 on which the mask case 600 is placed, and the neutralization mechanism that eliminates static electricity charged on the mask case 600 placed on the shelf portion 320. Specifically, the shelf portion 320 includes the conductive case support member 320c that comes into contact with a conductive portion (mask case support portion 611) of the mask case 600 and supports the mask case 600 from below, and the conductive frame portion 320b to which the case support member 320c is fixed. The neutralization mechanism electrically connects the case support member 320c and the frame portion 320b, and grounds the frame portion 320b, thereby eliminating the static electricity charged on the mask case 600. This allows static electricity charged on the mask case 600 to be discharged while the mask case 600 is accommodated in the mask buffer 310 (step S17 in FIG. 10, step S37 in FIG. 11). Therefore, the pattern formed on the mask M stored in the mask case 600 can be inhibited from being damaged by the discharge phenomenon of static electricity.

In the present embodiment, the buffer arm 330 that carries out the mask case 600 from the mask buffer 310 that stocks the mask case 600 and carries in the mask case 600 to the mask buffer 310 includes the arm portion 331 that is driven in a direction parallel to the surface of the mask M to take out the mask case 600 from the mask buffer 310 and insert the mask case 600 into the mask buffer 310, and the neutralization mechanism 340 that eliminates static electricity charged on the arm portion 331. The arm portion 331 is electrically connected to the mask case 600 while holding the mask case 600. This allows the static electricity charged on the mask case 600 to be eliminated while the mask case 600 is being transported by the buffer arm 330 (step S19 in FIG. 10). Therefore, the pattern formed on the mask M accommodated in the mask case 600 can be inhibited from being damaged by the discharge phenomenon of static electricity.

In the present embodiment, the arm portion 331 includes the conductive main body portion 331a, and the pedestal portion 331c that is electrically connected to the main body portion 331a and supports the mask case 600. The neutralization mechanism 340 includes the third electrode component 341 that is electrically connected to the main body portion 331a and contacts a conductive portion (positioning portion 612) of the mask case 600 supported by the pedestal portion 331c to guide the static electricity charged on the mask case 600 to the main body portion 331a. This allows static electricity charged on the mask case 600 to be guided to the main body portion 331a while the arm portion 331 supports the mask case 600.

In the present embodiment, the buffer arm 330 includes the first frame 332 that holds the first driving mechanism 333 that drives the arm portion 331 in the X-axis direction, and the second frame 334 that holds the second driving mechanism 335 that drives the first frame 332 in the Z-axis direction substantially orthogonal to the surface of the mask M. The neutralization mechanism 340 includes the first neutralization brush 342 that faces the arm portion 331 and guides the static electricity charged on the arm portion 331 (the main body portion 331a) to the first frame 332, and the second neutralization brush 343 that faces the first frame 332 and guides the static electricity charged on the first frame 332 to the second frame 334, and the second frame 334 is grounded. This allows static electricity guided from the mask case 600 to the main body portion 331a to be discharged to the ground via the first neutralization brush 342, the first frame 332, the second neutralization brush 343, and the second frame 334.

In the present embodiment, the first neutralization brush 342 guides the static electricity charged on the arm portion 331 to the first frame 332 when the arm portion 331 is located closest to the mask buffer 310 in the X-axis direction and when the arm portion 331 is located closest to the second frame 334 in the X-axis direction. This allows the static electricity charged on the mask case 600 to be eliminated when removing the mask case 600 from the mask buffer 310 and when returning the mask case 600 to the mask buffer 310.

According to the present embodiment, the mask transfer mechanism 370 that transfers the mask M to the main body 100 includes the holding portion 371 that holds the mask M and the neutralization mechanism 380 that eliminates static electricity charged on the holding portion 371. This allows the static electricity charged on the mask case 600 to be discharged while the mask M is being transferred by the mask transfer mechanism 370 (steps S20 and S23 in FIG. 10, step S33 in FIG. 11). Therefore, the pattern formed on the mask M accommodated in the mask case 600 can be inhibited from being damaged by the discharge phenomenon of static electricity.

In the series of processes related to the mask M illustrated in FIG. 10 and FIG. 11, when the mask M is carried into the PPD 390 (FIG. 10: step S21), when the mask M is loaded on the mask stage 114 (FIG. 10: step S25), when the mask M is unloaded from the mask stage 114 (FIG. 11: step S31), and when the mask M is taken out from the mask case 600 (FIG. 11: step S43), the static electricity charged on the mask M has been conventionally removed by an X-ray ionizer or the like, but the process of removing the static electricity charged on the mask M has not been performed in other steps. According to the present embodiment, since measures are taken to eliminate the static electricity charged on the mask M in each step other than step S21 of FIG. 10, step S25 of FIG. 10, step S31 of FIG. 11, and step S43 of FIG. 11, it is possible to further inhibit the pattern formed on the mask M from being damaged by the discharge phenomenon of static electricity.

In the above embodiment, an X-ray ionizer may be provided instead of the neutralization brush 500. In this case, the X-ray ionizer may be provided so that the surface on the opposite side of the substrate tray 201 from the surface holding the substrate P is irradiated with X-rays.

In the above embodiment, the conductive mask support member 603 is provided on the first case portion 601a, and the neutralization brush 604 is provided on the second case portion 601b, but the neutralization brush 604 may be omitted, for example. Alternatively, in the case where the neutralization brush 604 is provided, the mask support member 603 may be non-conductive.

In the above embodiment, a neutralization brush having conductive bristle bundles that are electrically connected to the first case portion 601a and extend toward the mask M may be provided on the first case portion 601a.

In the buffer arm 330 of the above embodiment, the third electrode component 341 is electrically connected to the positioning portion 612 of the mask case 600, but this does not intend to suggest any limitation. For example, the third electrode component 341 may be provided on the pedestal portion 331c and electrically connected to the mask case support portion 611 of the mask case 600.

Further, in the above embodiment, the exposure device EX is described as an exposure device using the mask M, but the mechanism for eliminating static electricity charged on the substrate P can also be applied to a so-called maskless exposure device that forms a pattern by, for example, a spatial light modulator instead of the mask M.

In the above embodiment, some of the neutralization mechanisms may be omitted.

In the above embodiment, a discharge cable may be provided to the member that is grounded in the above embodiment so that the grounded member does not have to be grounded.

Further, in the above embodiment, the case has been described where the exposure device EX is an exposure device that transfers the pattern of the mask M onto the substrate P, but the exposure device EX may be, for example, a semiconductor exposure device that forms a pattern formed on a reticle onto a wafer.

The above embodiments are preferred examples of the present disclosure. However, the present disclosure is not limited to the above, and various modifications can be made without departing from the scope of the present disclosure.

The following supplementary notes are further disclosed in relation to the above embodiment.

Supplementary Note 1

A mask case comprising:

a case body at least a part of which has conductivity, the case body accommodating a mask;

a conductive member that guides static electricity charged on the mask to the part having conductivity of the case body;

a first neutralization member that is electrically connected to the part having conductivity and eliminates static electricity charged on the part having conductivity.

Supplementary Note 2

The mask case according to supplementary note 1, wherein the first neutralization member is a discharge cable.

Supplementary Note 3

The mask case according to supplementary note 1 or 2,

wherein the case body includes:

a first case portion having a bottom surface; and

a second case portion that is detachably provided to the first case portion and has a ceiling surface disposed to face the bottom surface, and

wherein at least one of the first case portion or the second case portion includes the part having conductivity.

Supplementary Note 4

The mask case according to supplementary note 3,

wherein the first case portion has conductivity,

wherein the conductive member includes a first conductive member that is provided on the bottom surface so as to face the mask and guides static electricity charged on the mask to the first case portion, and

wherein the first neutralization member is provided to the outer side of the first case portion and eliminates static electricity charged in the first case portion.

Supplementary Note 5

The mask case according to supplementary note 4, wherein the first conductive member includes a plurality of conductive support members that are electrically connected to the first case portion and support the mask by being in contact with the mask.

Supplementary Note 6

The mask case according to supplementary note 5, further comprising:

a first electrode member electrically connecting the plurality of conductive support members and the first case portion; and

a second electrode member electrically connecting the first case portion and the first neutralization member.

Supplementary Note 7

The mask case according to any one of supplementary notes 4 to 6, wherein the first conductive member includes a neutralization brush that is electrically connected to the first case portion and has a conductive bristle bundle extending toward the mask.

Supplementary Note 8

The mask case according to supplementary note 7, further comprising a third electrode member that electrically connects the neutralization brush and the first case portion.

Supplementary Note 9

The mask case according to any one of supplementary notes 4 to 8,

wherein the second case portion has conductivity,

wherein the conductive member includes a second conductive member that is provided on the ceiling surface of the second case portion, faces the mask, and guides static electricity charged on the mask to the second case portion, and

wherein the first case portion and the second case portion are electrically connected to each other in a state where the second case portion is attached to the first case portion.

Supplementary Note 10

The mask case according to supplementary note 9, further comprising:

a fourth electrode member electrically connecting the second case portion and the second conductive member; and

a fifth electrode member electrically connecting the first case portion and the second case portion.

Supplementary Note 11

The mask case according to supplementary note 9 or 10, wherein the second conductive member is a neutralization brush having a conductive bristle bundle extending toward the first case portion.

Supplementary Note 12

A transport cart for transporting the mask case according to any one of supplementary notes 1 to 11, the transport cart comprising:

a placement portion on which the mask case is placed; and

a neutralization mechanism that eliminates static electricity charged on the mask case placed on the placement portion.

Supplementary Note 13

The transport cart according to supplementary note 12,

wherein the neutralization mechanism includes:

a first electrode component electrically connected to the part having conductivity of the mask case; and

a third neutralization member that is electrically connected to the first electrode component and eliminates static electricity charged on the mask case.

Supplementary Note 14

The transport cart according to supplementary note 13,

wherein the neutralization mechanism includes a fifth electrode member electrically connected to the first electrode component,

wherein the fifth electrode member is electrically connected to a second electrode component that is disposed at a predetermined location and is grounded when the transport cart is positioned in the predetermined location.

Supplementary Note 15

A mask buffer capable of stocking a plurality of mask cases according to any one of supplementary notes 1 to 11, the mask buffer comprising:

a shelf portion on which the mask case is placed; and

a neutralization mechanism that eliminates static electricity charged on the mask case placed on the shelf portion.

Supplementary Note 16

The mask buffer according to supplementary note 15,

wherein the shelf portion includes:

a case support portion that has conductivity, comes into contact with the part having conductivity of the mask case, and supports the mask case from below; and

a frame portion to which the case support portion is fixed, the frame portion having conductivity, and

wherein the neutralization mechanism eliminates static electricity charged on the mask case by electrically connecting the case support portion and the frame portion and grounding the frame portion.

Supplementary Note 17

A transfer device that carries out the mask case from a mask buffer that stocks the mask case according to any one of supplementary notes 1 to 11 and carries in the mask case to the mask buffer, the transfer device comprising:

an arm portion that is driven in a first direction parallel to a surface of the mask to take out the mask case from the mask buffer and insert the mask case into the mask buffer; and

a neutralization mechanism that eliminates static electricity charged on the arm portion,

wherein the arm portion is electrically connected to the mask case in a state where the arm portion holds the mask case.

Supplementary Note 18

The transfer device according to supplementary note 17,

wherein the arm portion includes:

a main body portion having conductivity; and

a support member that supports the mask case,

wherein the neutralization mechanism includes a third electrode component that is electrically connected to the main body portion, and comes into contact with the part having conductivity of the mask case supported by the support member to guide static electricity charged on the mask case to the main body portion.

Supplementary Note 19

The transfer device according to claim 17 or 18, further comprising:

a first frame that holds a first drive mechanism that drives the arm portion in the first direction; and

a second frame that holds a second driving mechanism that drives the first frame in a second direction substantially orthogonal to a surface of the mask,

wherein the neutralization mechanism includes:

a fourth neutralization member that faces the arm portion and guides static electricity charged on the arm portion to the first frame; and

a fifth neutralization member that faces the first frame and guides static electricity charged on the first frame to the second frame, and

wherein the second frame is grounded.

Supplementary Note 20

The transfer device according to supplementary note 19, wherein the fourth neutralization member guides static electricity charged on the arm portion to the first frame when the arm portion is located closest to the mask buffer in the first direction and when the arm portion is located closest to the second frame in the first direction.

Supplementary Note 21

The transfer device according to supplementary note 19 or 20, wherein the fifth neutralization member guides static electricity charged on the first frame to the second frame at least one of the following timings: when the first frame is at a highest position in the second direction and when the first frame is at a lowest position in the second direction.

Supplementary Note 22

The transfer device according to any one of supplementary notes 19 to 21, wherein the fourth neutralization member and the fifth neutralization member are neutralization brushes having conductive bristle bundles.

Supplementary Note 23

A transfer device that transfers a mask to a main body of an exposure device, the transfer device comprising:

a holding portion that to holds the mask; and

a neutralization mechanism that eliminates static electricity charged on the holding portion.

Supplementary Note 24

The transfer device according to supplementary note 23,

wherein the holding portion includes a support portion that has conductivity, is in contact with the mask, and supports the mask, and

wherein the neutralization mechanism eliminates the static electricity charged on the holding portion by guiding static electricity charged on the support portion to another member that is grounded.

Supplementary Note 25

The transfer device according to supplementary note 24,

wherein the holding portion includes an arm portion to which the support portion is fixed, the arm portion being drivable in a first direction parallel to a surface of the mask,

wherein the neutralization mechanism includes:

a connection portion that electrically connects the support portion and the arm portion and guides static electricity charged on the support portion to the arm portion; and

a sixth neutralization member that guides static electricity charged on the arm portion to a housing that is grounded and houses the arm portion.

Supplementary Note 26

The transfer device according to supplementary note 25, wherein the connection portion is a plate-shaped member having elasticity.

Supplementary Note 27

The transfer device according to supplementary note 25 or 26, wherein the sixth neutralization member guides static electricity charged on the arm portion to the housing when the holding portion holds the mask.

Supplementary Note 28

The transfer device according to any one of supplementary notes 25 to 27, wherein the sixth neutralization member is a neutralization brush having a conductive bristle bundle.

What is claimed is:

1. An exposure device comprising:
a neutralization portion that eliminates static electricity charged on a substrate support member while the substrate support member supporting a substrate moves,
wherein the substrate support member includes a main body portion that is conductive, and a conductive member that faces the substrate supported by the substrate support member and is electrically connected to the main body portion, and
wherein the neutralization portion eliminates static electricity charged on the main body portion.

2. The exposure device according to claim 1, wherein the neutralization portion is provided in a third region located between a first region where static elimination is performed on the substrate and a second region different from the first region, and eliminates static electricity charged on the substrate support member while the substrate support member moves through the third region.

3. The exposure device according to claim 1,
wherein the first region is a substrate holder on which the substrate is placed during exposure of the substrate, and
wherein the second region is a pedestal unit that is used to deliver the substrate between an external device and the exposure device.

4. The exposure device according to claim 1, wherein the neutralization portion is provided to face a surface on an opposite side of the substrate support member from a surface holding the substrate.

5. The exposure device according to claim 1, wherein the neutralization portion does not contact the substrate support member.

6. The exposure device according to claim 1, wherein the neutralization portion is an ionizer.

7. The exposure device according to claim 1, wherein the neutralization portion is a neutralization brush having a conductive bristle bundle extending toward the substrate support member.

8. The exposure device according to claim 6, wherein the neutralization portion extends in a direction intersecting a moving direction of the substrate support member.

9. The exposure device according to claim 1, wherein the conductive member includes a neutralization brush that has a conductive bristle bundle extending toward the substrate.

10. The exposure device according to claim 1, wherein the conductive member includes a plurality of support members that support the substrate by being in contact with the substrate.

11. The exposure device according to claim 1, wherein the substrate support member includes a discharge cable electrically connected to the main body portion.

12. The exposure device according to claim 1, further comprising
a transfer device that transfers the substrate support member.

13. A substrate support member that supports a substrate to be moved, comprising:
a main body portion that is conductive;
a conductive member that faces the substrate and is electrically connected to the main body portion; and
a discharge cable electrically connected to the main body portion.

14. A substrate support member that supports a substrate to be moved, comprising:
a main body portion that is conductive;
at least one of a neutralization brush or a support member having conductivity, the neutralization brush being electrically connected to the main body portion and having a conductive bristle bundle extending toward the substrate, the support member being electrically connected to the main body portion, supporting the substrate by being in contact with the substrate, and having conductivity; and
a discharge cable electrically connected to the main body portion.

15. An exposure device comprising:
a neutralization portion that eliminates static electricity charged on a substrate support member while the substrate support member supporting a substrate moves,
wherein the substrate support member includes:
a main body portion that is conductive; and
at least one of a neutralization brush or a support member having conductivity, the neutralization brush being electrically connected to the main body portion and having a conductive bristle bundle extending toward the substrate, the support member being electrically connected to the main body portion and configured to support the substrate by being in contact with the substrate, and
wherein the neutralization portion eliminates static electricity charged on the main body portion.
